(19) United States
(12) Patent Application Publication
(10) Pub. No.: US 2008/0217709 A1
(43) Pub. Date: Sep. 11, 2008

(54) MEMS PACKAGE HAVING AT LEAST ONE PORT AND MANUFACTURING METHOD THEREOF

(75) Inventors: Anthony Minervini, Palos Hills, IL (US); Gwendolyn P. Massingill, Aurora, IL (US)

Correspondence Address: FITCH EVEN TABIN AND FLANNERY, 120 SOUTH LA SALLE STREET, SUITE 1600, CHICAGO, IL, 60603-3406, US

(73) Assignee: KNOWLES ELECTRONICS, LLC, Itasca, IL (US)

(21) Appl. No.: 12/034,764

(22) Filed: Feb. 21, 2008

Related U.S. Application Data
(60) Provisional application No. 60/893,500, filed on Mar. 7, 2007.

(51) Int. Cl. H01L 23/053; H01L 21/52

(52) U.S. Cl. 257/416; 438/51; 438/111; 257/E23.188; 257/E21.5

(57) ABSTRACT

A plurality of individual MEMS packages are formed as a contiguous unit and each of the plurality of individual MEMS packages include at least one acoustic port. One or more separation boundaries from where to separate adjacent ones of the plurality of individual MEMS packages are determined. Each of the plurality of individual MEMS packages are subsequently separated from the others according to the one or more separation boundaries to provide separate and distinct individual MEMS packages. Each acoustic port disposed within each separate and distinct individual MEMS package is exposed due to the separating so as to allow sound energy to enter each separate and distinct individual MEMS package.

### CROSS REFERENCES TO RELATED APPLICATIONS

This patent claims priority to provisional application 60/893,500 filed Mar. 7, 2007, entitled MEMS PACKAGE HAVING AT LEAST ONE PORT AND MANUFACTURING METHOD THEREOF, and having named inventors of Anthony D. Minervini and Gwendolyn P. Massingill, the contents of which are incorporated herein in their entirety.

### BACKGROUND

Mobile communication technology advancements have progressed rapidly in recent years. Consumers are increasingly using mobile communication devices such as cellular phones, web-enabled cellular telephones, Personal Digital Assistants (PDA), hand-held computers, laptops, tablets or any other similar devices. Generally, a cellular phone includes a housing and a printed circuit board (PCB) within the housing. An acoustic transducer may have a surface for electrically coupling the transducer to the PCB and is secured within the housing. At least one acoustic pathway couples an acoustic port of the transducer to an exterior surface of the housing. The housing may have at least one sound opening for porting acoustical signals between the transducer and the user via the acoustic port and the acoustic pathway. Mounting the transducer within the housing can be problematic in some types of cellular phones because the location of sound opening in the cellular phone is largely dependent upon the location of the transducer acoustic port inside the cellular phone. Further, the acoustic port of the transducer is formed by drilling through the transducer housing or molding the acoustic port into the transducer housing resulting in considerably less efficiency during the manufacturing process.

### BRIEF DESCRIPTION OF THE DRAWINGS

For a more complete understanding of the disclosure, reference should be made to the following detailed description and accompanying drawings wherein:

FIG. 1 is a perspective view of a MEMS package utilized in various types of devices according to various embodiments of the invention;

FIG. 2 is a perspective view illustrating a MEMS package according various embodiments to the invention;

FIGS. 3-11 are cross-sectional views of a MEMS package, in accordance with various embodiments of the invention;

FIGS. 12-20 are cross-sectional views of another exemplary MEMS package, in accordance with various embodiments of the invention;

FIGS. 21-29 are cross-sectional views of another exemplary dual MEMS package, in accordance with various embodiments of the invention;

FIGS. 30-36 are cross-sectional views of another exemplary MEMS package, in accordance with various embodiments of the invention;

FIGS. 37-42 are cross-sectional views of another exemplary MEMS package, in accordance with various embodiments of the invention;

FIGS. 43-48 are cross-sectional views of another exemplary MEMS package, in accordance with various embodiments of the invention;

FIG. 49 is a plan view of a panel of a plurality of MEMS packages, in accordance with various embodiments of the invention;

FIG. 50 is a cross sectional view of a communication device incorporating a MEMS package, in accordance with various embodiments of the invention;

FIG. 51 is a cross-sectional view of another described example of a communication device incorporating a MEMS package, in accordance with various embodiments of the invention;

FIG. 52 is a cross-sectional view of another described example of a communication device incorporating a MEMS package, in accordance with various embodiments of the invention;

FIGS. 53-59 are cross-sectional views of a folded MEMS package, in accordance with various embodiments of the invention;

FIGS. 60-62 are cross-sectional views of an exemplary folded MEMS package, in accordance with various embodiments of the invention; and

FIG. 63 is a cross sectional view of a communication device incorporating a MEMS package, in accordance with various embodiments of the invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

While this disclosure is susceptible to various modifications and alternative forms, certain embodiments are shown by way of example in the drawings and these embodiments will be described in detail herein. It will be understood, however, that this disclosure is not intended to limit the invention to the particular forms described, but to the contrary, the invention is intended to cover all modifications, alternatives, and equivalents falling within the spirit and scope of the invention defined by the appended claims.

In many of these embodiments, a plurality of individual MEMS packages are formed as a contiguous unit and each of the plurality of individual MEMS packages include at least one acoustic port. One or more separation boundaries from where to separate adjacent ones of the plurality of individual MEMS packages are determined. Subsequently, each of the plurality of individual MEMS packages are separated from the others according to the one or more separation boundaries in order to provide separate and distinct individual MEMS packages. Each acoustic port that is disposed within each separate and distinct individual MEMS package is exposed because of the separating so as to allow sound energy to enter each separate and distinct individual MEMS package.

In one example, the contiguous unit may be mounted on a mounting tape. In another example, the continuous unit may be held by a vacuum. Other approaches for securing the contiguous unit are possible. Once secured, the separating may be achieved by a variety of processes such as sawing, laser cutting, scribing, and breaking. Other separating processes are possible.

In other examples, a protective coating is at least partially applied to each of the plurality of individual MEMS packages. Subsequent to the separating, each of the separate and distinct individual MEMS packages is cured to remove the coating.

The MEMS packages may be structured and formed in a variety of different ways. In one example, individual MEMS package may be formed with a first structure and a second structure attached to the first structure. Additionally, each of the individual MEMS packages may be formed to include a cavity. An electronic device and a MEMS die may be disposed within the cavity. Further, the MEMS packages may be formed as a single MEMS package or a dual MEMS package.

In others of these embodiments, a MEMS package is formed and includes an elongated base. One or more MEMS devices are disposed onto the elongated base. A first portion of the base at least partially surrounds the one or more MEMS devices and forms at least one acoustic port that allows sound energy to be received at the one or more MEMS devices.

The first portion of the base may be folded in a number of ways, shapes, or configurations. In one approach, the first portion of the base may be folded so as to provide a side wall for the MEMS device. In another example, the first portion of the base may be folded so as to provide a cover for the MEMS device. In another example, the first portion of the base may be folded so as to be at least partially under a remaining portion of the base. Combinations of these examples may also be used. Additionally, other folding arrangements and configurations are possible.

The MEMS device itself may be a MEMS die and an electronic device. In one example, the electronic device is an integrated circuit and the MEMS die is a microphone.

In others of these embodiments, a micro-electromechanical system (MEMS) package is provided. The MEMS package includes a base and a first structure disposed upon the base. A second structure is disposed on the first structure and the second structure is configured to form a first cavity and has at least one side wall attached to the first structure. At least one MEMS die is disposed in the cavity and a first acoustic port is formed through the sidewall. The first acoustic port provides a passageway to allow sound energy to enter the MEMS package and to be received at the MEMS die.

In other examples, the MEMS package further includes an electronic device. In one example, the electronic device is an integrated circuit. In some examples, the MEMS die is a microphone.

In still other examples, the MEMS package is disposed within a cavity of an electronic apparatus and the electronic apparatus includes a second acoustic port for providing a second passageway to allow sound energy to be received in the second cavity of the electronic apparatus from outside the portable electronic apparatus. In one example, the electronic apparatus is a cellular phone. Other examples of the portable electronic apparatus are possible.

In still others of these embodiments, a micro-electromechanical system (MEMS) package includes a MEMS structure and the MEMS structure includes an elongated base. At least one MEMS device is disposed onto the elongated base and a first folded portion of the elongated base is arranged in folded relation to a remaining portion of the elongated base so as to at least partially surround the at least one MEMS device and form at least one acoustic port allowing sound energy to be received at the MEMS device.

The first folded portion of the elongated base of the MEMS package may be arranged or configured in a variety of different ways. In one example, the first folded portion provides a side wall for the MEMS package. In another example, the first folded portion provides a cover for the MEMS package. In another example, the first folded portion is at least partially under the remaining portion of the base. Combinations of these arrangements may be used and other examples are possible.

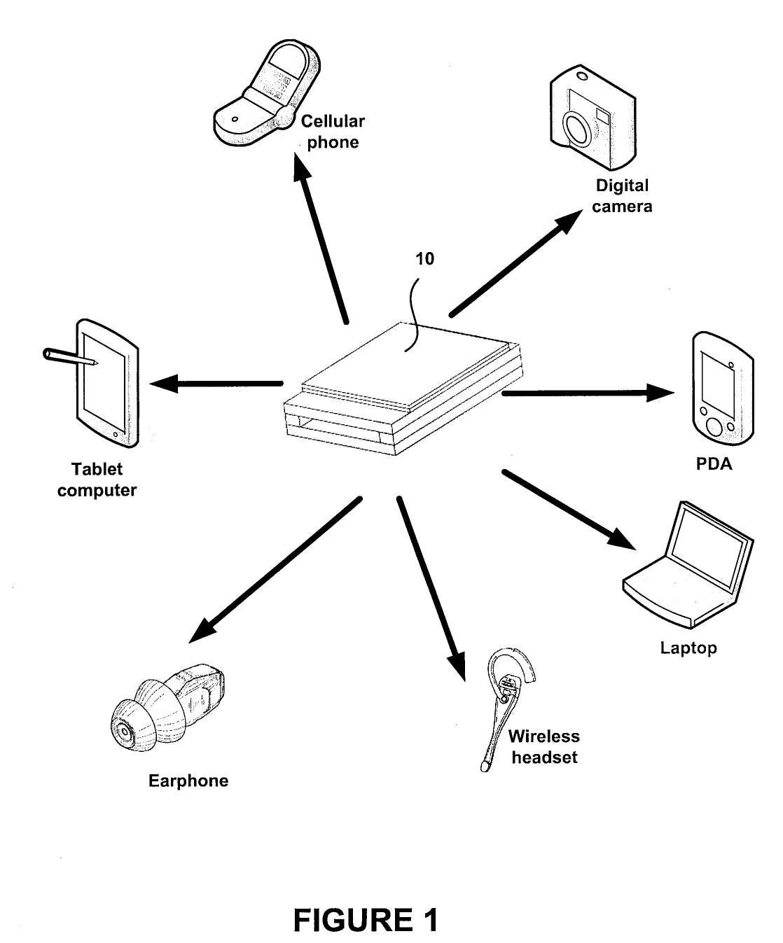

Turning now to the figures, FIG. 1 illustrates the flexibility and usefulness of a package 10 in accordance with one or more of the herein described embodiments. Microelectromechanical system (MEMS) assemblies and approaches for manufacturing these packages are provided. The packages provided possess small dimensions and are, consequently, suitable for inclusion in small and/or thin electronic devices. In this regard these packages can be included in various types of devices, such as computers (e.g., desktops, laptops, notebooks, tablet computers, hand-held computers, Personal Digital Assistants (PDAs), Global Positioning systems (GPS), security systems), communication devices (e.g., cellular phones, web-enabled cellular telephones, cordless phones, pagers), computer-related peripherals (e.g., printers, scanners, monitors), entertainment devices (e.g., televisions, radios, satellite radios, stereos, tape and computer disc players, digital cameras, cameras, video cassette recorders, Motion Picture Expert Group, Audio Layer 3 (MP3) players, video games), listening devices (e.g., hearing aids, earphones, headphones, Bluetooth wireless headsets, insert earphone, UWB wireless headsets) and the like. Other examples of devices are possible. Further, these packages significantly reduce or eliminate the effects of electromagnetic interference EMI). Since these packages are small and easy to manufacture, manufacturing costs are reduced and reliability is enhanced.

In many of these embodiments, a package 10 comprises a die and an electronic device. The die may be a speaker, a receiver, a MEMS based silicon receiver, a dual receiver, an electret microphone, a dynamic microphone, a MEMS based silicon microphone, a dual microphone, a conjoined microphone and receiver, depending on the desired applications. The electronic device may be an integrated circuit (IC), a capacitor, a resistor, an inductor, or other passive device, depending on the desired applications. It will be understood that one or more dies and electronic components may be included. The die and the IC may be integrated into a single chip. Alternatively, the die may be wire bonded directly to the IC by wires.

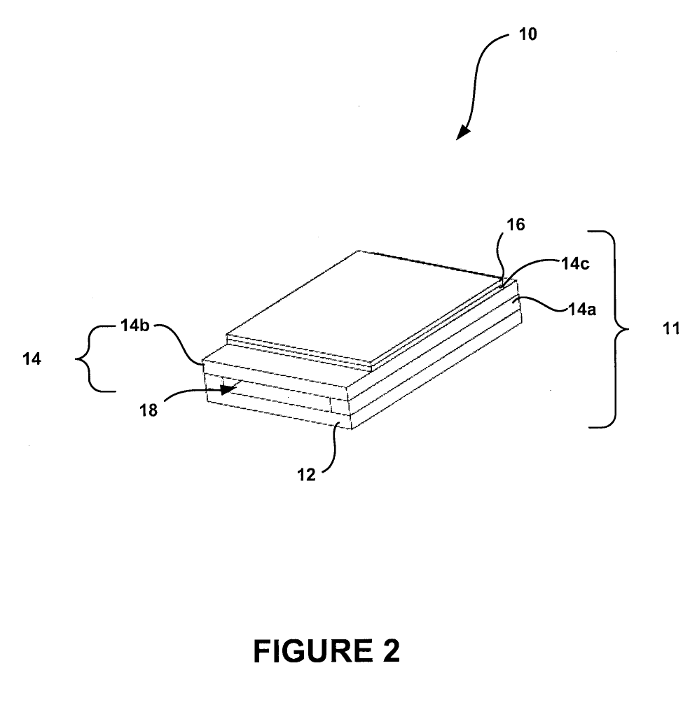

With reference to FIG. 2, a package 10 may include a housing 11 having a base 12, a spacer 14, and a lid 16 attached together by a conductive adhesive, solder, or a combination of a conductive adhesive or solder with a non-conductive adhesive (not shown). A cavity (not shown) is formed within the housing 11. The cavity may be a back volume, a front volume, or a mixed volume. The base 12 and the lid 16 are shown as having at least one layer. However, the base 12 and the lid 16 may utilize multiple layers, and such examples are discussed in greater detail herein. The spacer 14 is shown as having multiple layers 14a, 14b, and 14c; however, the spacer 14 may utilize a single layer, and such examples are discussed in greater detail herein. Although the base 12, spacer 14, and the lid 16 are depicted, it is possible to eliminate one of the structures 12, 14, 16 or add additional structures. For example, the spacer 14 may be integrated with either the base 12 or the lid 16 as a single structure to form a cap with four side walls. Alternatively, in some cases, a second housing may be added to couple with the first housing 11 in back-to-back alignment to form a stacked package. The die and the electronic component are disposed within the housing 11. The housing 11 protects the die and the electronic component from light, electromagnetic interference (EMI), and physical damage. The package 10 may include a single port or multiple ports, depending on the desired applications. As shown, the port 18 is formed on the side wall of the housing 11 using a dicing process for the purpose of providing a sound path leading to the die disposed within the housing 11. The port 18 may take the form of various shapes (e.g. circular, square-shaped, or rectangular-shaped) and have a number of different sizes. A second port (not shown) may be formed on the housing 11 to provide directional characteristics, i.e. omni-directional, bi-directional, or uni-directional sensitivity. More details about the formation of the side ports are described in the present disclosure.

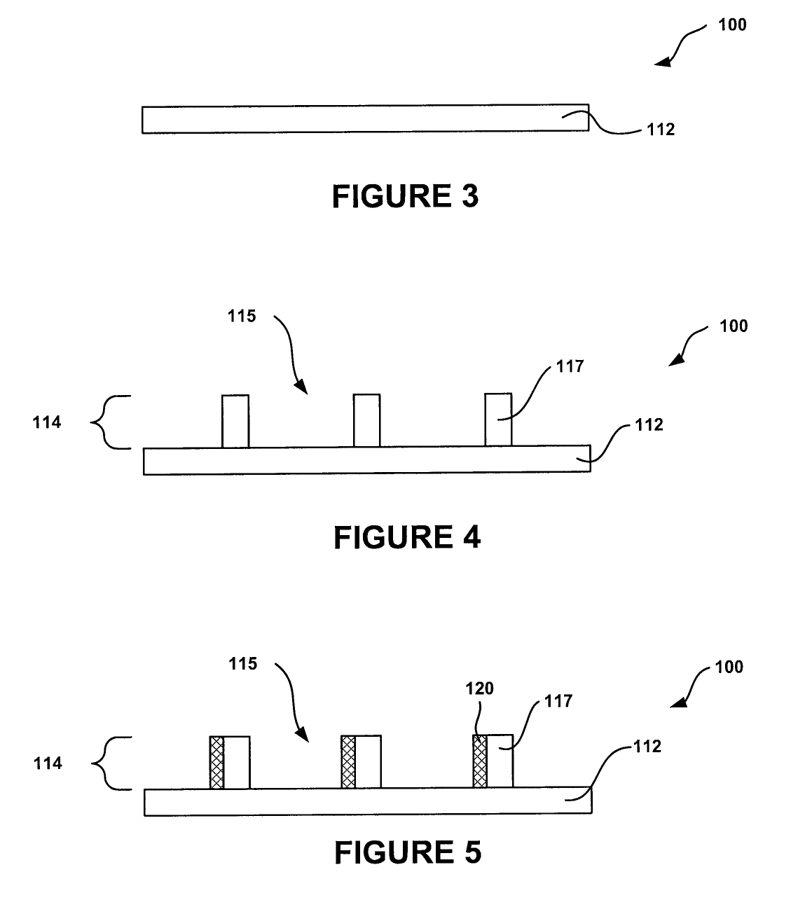

FIGS. 3-11 illustrate one process of forming an acoustic port 118 during a separation process. FIGS. 3-11 are similar in construction to the package 10 in FIGS. 1-2 and like elements are identified with a like reference convention wherein, for example, element 12 corresponds to element 112. As illustrated in FIG. 3, a first structure 112 is provided as a base of the package 100. The base 112 can be formed from a printed circuit board (PCB), a flexible circuit, a foldable circuit, a ceramic substrate, a thin film multichip module substrate, a prefolded substrate, a combination thereof, or similar substrate material. The base 112 may be a rigid or flexible support for embedded electronic components. The base 112 may be made of conductive material, non-conductive material, or a combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating.

Referring now to FIG. 4, a second structure 114 is attached to the first structure 112 by a conductive adhesive, solder, or a combination of a conductive adhesive or solder with a non-conductive adhesive (not shown). The second structure 114 is provided as a spacer having a cavity 115 surrounded by side walls 117. The spacer 114, which may be the same material as the first structure 112, may utilize one or multiple layers. For example, the space 114 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic.

As shown in FIG. 5, a portion of the cavity 115 is filled or covered by a protective coating 120 using evaporation, condensation, spin coating, spraying, brushing, flow coating, or screen printing, depending on the desired applications to protect the die and the electronic device from shock, stress, and debris during dicing process. Other techniques may also be used. The protective coating 120 may be a water insoluble coating, although depending on the dicing method and whether it employs water-jets, water soluble coatings may be used. The protective coating 120 may be chosen from a set of materials that are in soft solid form, high vapor pressure or decomposition temperature near 150 degrees Celsius, no residue after removal, no tendency to create stiction. In one embodiment the protective coating 120 may be a polynorbornene (PNB) material, commonly available under the trade designation Unity from Promerus, LLC, or of any similar materials. Generally, this material may be applied as a liquid and cured to a solid with heat. Decomposition typically occurs at an elevated temperature range between 200° C. and 425° C. Alternatively, the protective coating 120 material may be chosen from a set of materials that can be evaporated or sublimated off the wafer for removal. One set of materials includes linear carbon chain molecules containing 12-18 carbon atoms. For example, the protective coating 120 may be Dodecanol, Heptadecanal, Heptadecanol, or chlorinated materials such as 2,6-dichloro-2,6-dimethylheptane. In one preferred embodiment, the protective coating 120 is Cetyl alcohol CH₃(CH₂)₁₅ OH also known as 1-Hexadecanol with a melting point greater than 24° C. and preferably less than 50° C., and a boiling point greater than 100° C. and preferably less than 150° C.

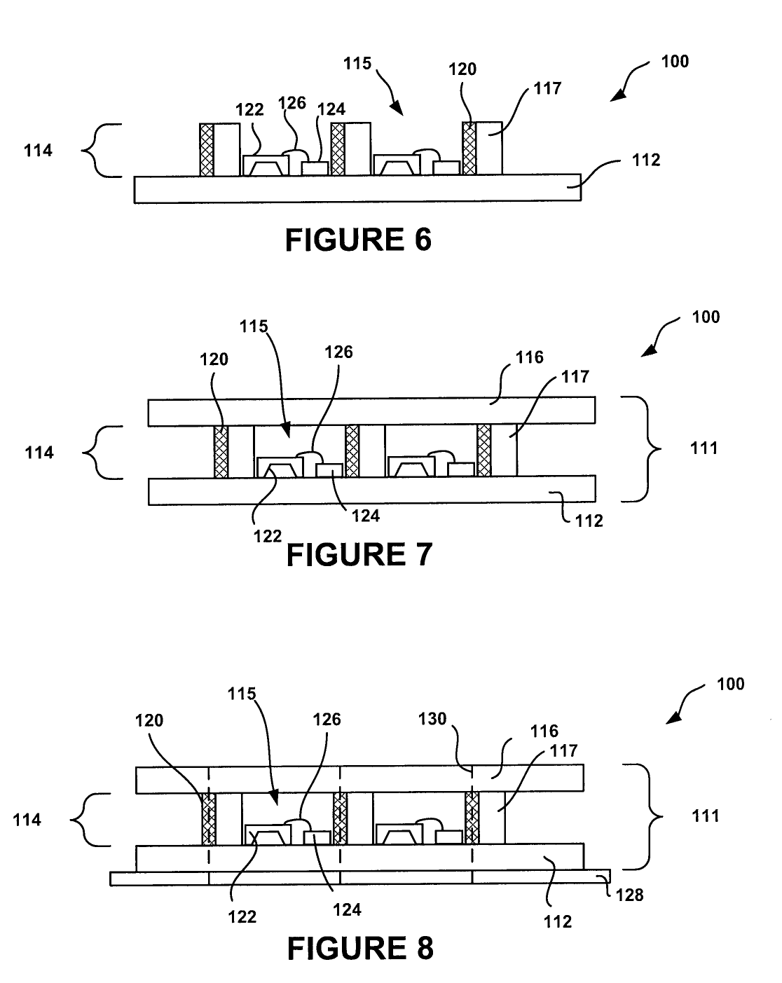

Now, as illustrated in FIG. 6, a MEMS die 122 and an electronic device 124 are disposed within the cavity 115 of the package 100. The MEMS die 122 is attached to the first structure 112 with an adhesive (not shown). For example, the electronic device 124 may be an IC that is attached to the first structure 112 with an adhesive (not shown). Alternatively, the electronic device 124 may be a passive component that is attached to the first structure 112 by a surface mounting technique (SMT). In one embodiment, the electronic device 124 is the IC and the MEMS die 122 is a microphone. The IC die 124 is then wire-bonded by wires 126 to the microphone 122 to a bond pad (not shown) on the microphone 122 and to a bond pad (not shown) on the first structure 112. The IC 124 and the microphone 122 may be integrated into a single chip that is attached to the first structure 112 using an adhesive in a die-attach process.

Referring now to FIG. 7, a third structure 116 is attached to the second structure 114 by a conductive adhesive, solder, or a combination of a conductive adhesive or solder with a non-conductive adhesive (not shown). The third structure 116 is provided as a lid of the package 100. The third structure 116 is similar to the first structure 112 and may utilize one or multiple layers. For example, the lid 116 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. As mentioned earlier, the third structure 116 may integrate with the second structure 114 as a single structure to form a cap with four side walls and the first structure 112 as a base is attached to the cap, defining a housing 111. An optional second housing may be added to couple with the first housing 111 in back-to-back alignment to form a stacked package. The housing 111 protects the microphone 122 and the IC 124 from light, EMI, and physical damage.

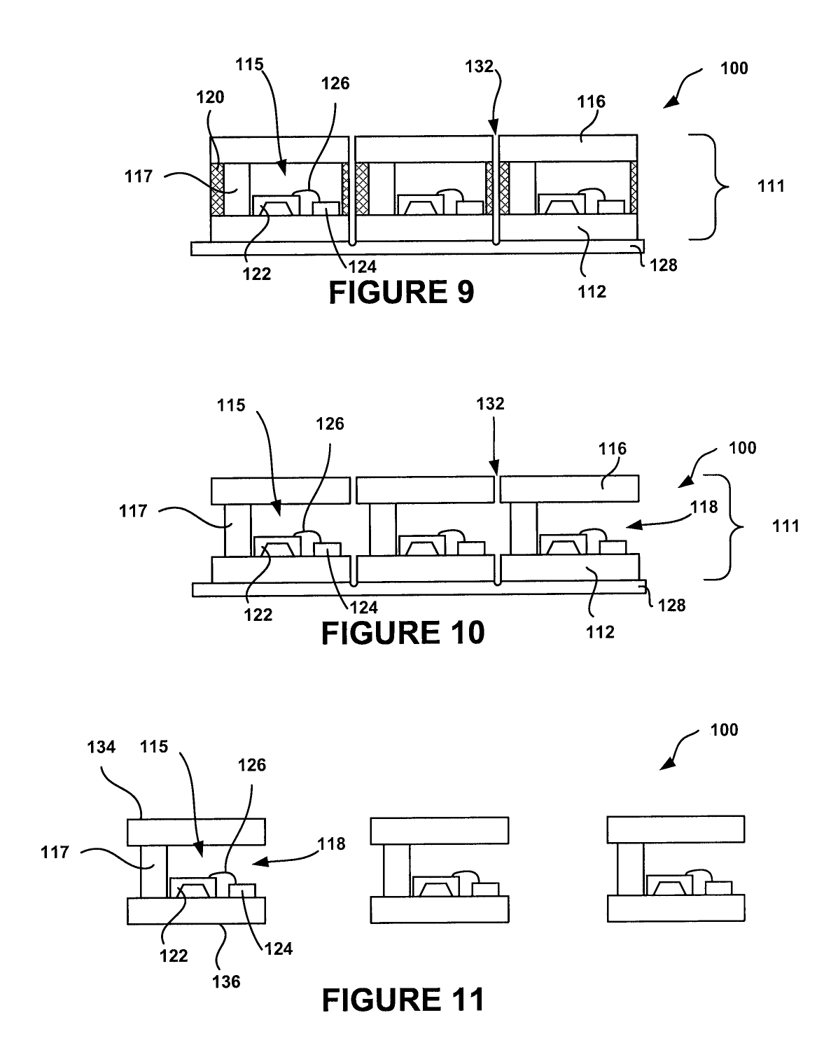

Referring now to FIG. 8, the package 100 is then mounted on an optional dicing tape 128 and subsequently diced along a dicing street 130 to produce a plurality of packages. Alternatively, the package 100 may be held by a vacuum and then singulated into a plurality of packages. The layer of dicing tape 128 may have a UV releasable adhesive. Other examples of tapes are possible. The dicing occurs through the housing 111 and through the protective coating 120 disposed within the housing 111, but the tape 128 is not cut through to produce cuts or saw kerfs 132, as shown in FIG. 9. The dicing may be realized by using a saw, a laser, scribing or breaking. Other examples of dicing processes are possible.

Now, as illustrated in FIG. 10, while the packages 100 are still remaining on the tape 128, the packages 100 are then transferred as is to a chamber (not shown) and cured at a temperature for a certain period until the protective coating 120 is completely removed from the cavity 115 of the housing 111. A port 118 is formed on the side wall adjacent to connecting walls 134, 136 of the housing 111 allowing the acoustic signals into the cavity 115 to interact with the microphone 122 mounted within the housing 111. One advantage of the package 100 is that, unlike the conventional packages, the port 118 of the package 100 is not formed by mechanically punching hole or drilling through the structures 112, 114, or 116. Dicing the housing 111 and then subsequently curing the protective coating 120 to form the port 118 for the purpose of providing a sound path leading to the dies 122, 124 disposed within the housing 111 simplifies the manufacturing process. Further, the manufacturing costs are reduced and reliability is enhanced.

As depicted in FIG. 11, the packages 100 together with the tape 128 are exposed by UV radiation (not shown). This exposure to the radiation is sufficient to break the bond between the tape 128 and the packages 100. Alternatively, the packages 100 can be released from the tape 128 using eject needles or a combination of UV, heat, eject needles, or other release techniques. Individual packages 100 are then lifted off from the tape 128 with die sorting equipment (not shown) ready for inspection, testing, or actual use.

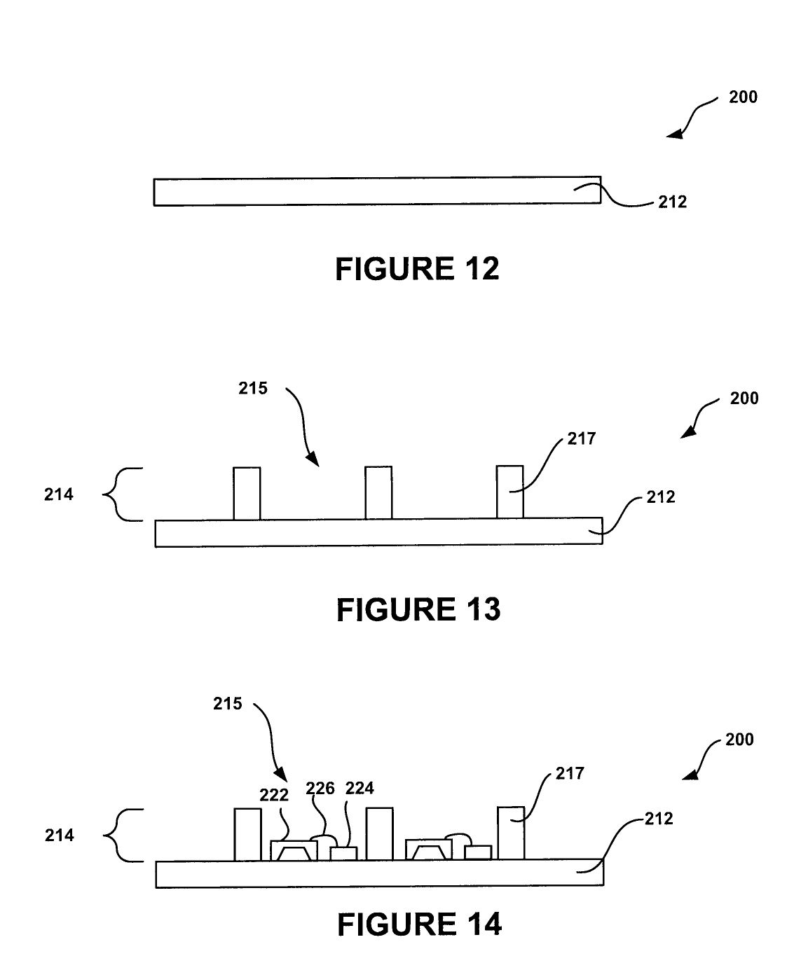

FIGS. 12-20 illustrate one process of forming an acoustic port 218 during a separation process. FIGS. 12-20 are similar in construction to the package 100 in FIGS. 3-11 and like elements are identified with a like reference convention wherein, for example, element 112 corresponds to element 212. As illustrated in FIG. 12, a first structure 212 is provided as a base of the package 200. The base 212 can be formed from a printed circuit board (PCB), a flexible circuit, a ceramic substrate, a thin film multichip module substrate, or similar substrate material. The base 212 may be a rigid or flexible support for embedded electronic components. The base 212 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating.

Referring now to FIG. 13, a second structure 214 is attached to the first structure 212 by a conductive adhesive, solder, or a combination of a conductive adhesive or solder with a non-conductive adhesive (not shown). The second structure 214 is provided as a spacer having a cavity 215 surrounded by side walls 217. The spacer 214, which may be the same material as the first structure 212, may utilize one or multiple layers. For example, the spacer 214 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic.

Now, as illustrated in FIG. 14, a MEMS die 222 and an electronic device 224 are disposed within the cavity 215 of the package 200. The MEMS die 222 is attached to the first structure 212 with an adhesive (not shown). For example, the electronic device 224 may be an IC that is attached to the first structure 212 with an adhesive (not shown). Alternatively, the electronic device 224 may be a passive component that is attached to the first structure 212 by a surface mounting technique (SMT). In one embodiment, the electronic device 224 is the IC and the MEMS die 222 is a microphone. The IC die 224 is then wire-bonded by wires 226 to the microphone 222 to a bond pad (not shown) on the microphone 222 and to a bond pad (not shown) on the first structure 212. The IC 224 and the microphone 222 may be integrated into a single chip that is attached to the first structure 212 using an adhesive in a die-attach process.

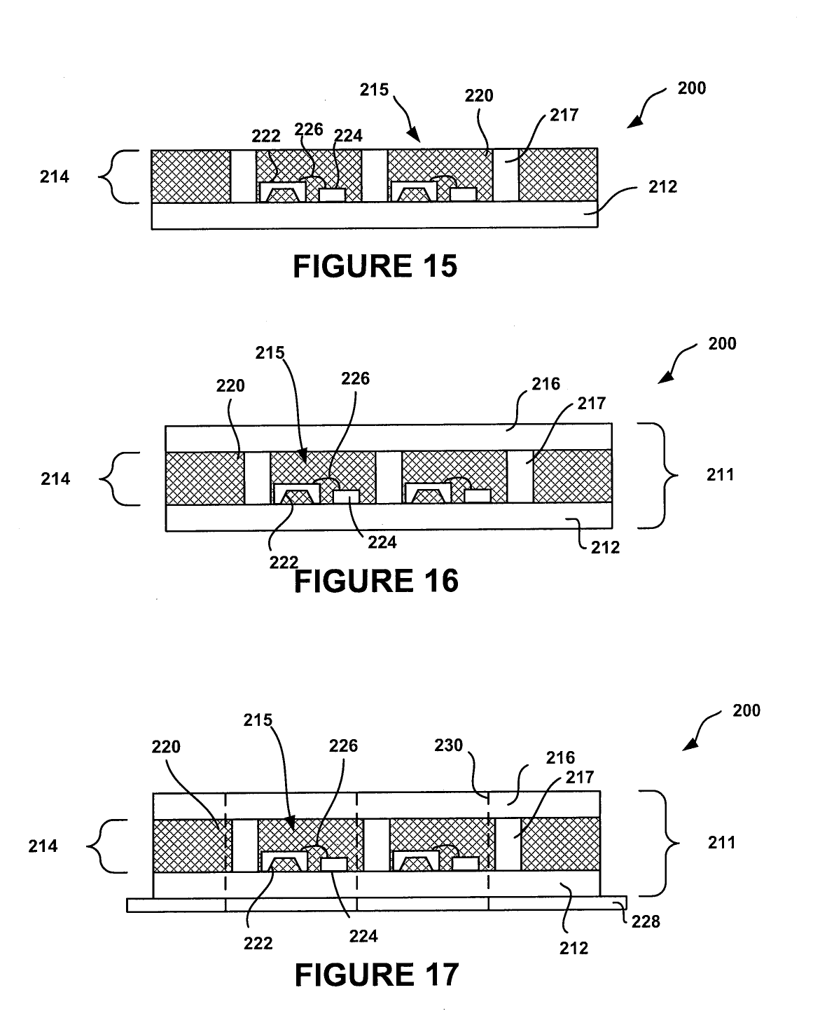

Referring now to FIG. 15, a protective coating 220 is applied to the cavity 215 using evaporation, condensation, spin coating, spraying, brushing, flow coating, or screen printing, depending on the desired applications to protect the dies 222, 224 from shock, stress, and debris during dicing process. Other techniques may also be used. The cavity 215 may be partially filled with the protective coating 220 after the dies 222, 224 are mounted to the first structure 212 but the dies 222 do not necessary have to be covered completely by the protective coating 220. The protective coating 220 may be a water insoluble coating, although depending on the dicing method and whether it employs water-jets, water soluble coatings may be used. The protective coating 220 may be chosen from a set of materials that are in soft solid form, high vapor pressure or decomposition temperature near 150 degrees Celsius, no residue after removal, no tendency to create stiction. In one embodiment the protective coating 220 may be a polynorbornene (PNB) material, commonly available under the trade designation Unity from Promerus, LLC, or of any similar materials. Generally, this material may be applied as a liquid and cured to a solid with heat. Decomposition typically occurs at an elevated temperature range between 200° C. and 425° C. Alternatively, the protective coating 220 material may be chosen from a set of materials that can be evaporated or sublimated off the wafer for removal. One set of materials includes linear carbon chain molecules containing 12-18 carbon atoms. For example, the protective coating 220 may be Dodecanol, Heptadecanal, Heptadecanol, or chlorinated materials such as 2,6-dichloro-2,6-dimethylheptane. In one preferred embodiment, the protective coating 120 is Cetyl alcohol CH₃(CH₂)₁₅ OH also known as 1-Hexadecanol with a melting point greater than 24° C. and preferably less than 50° C. and a boiling point greater than 100° C. and preferably less than 150° C.

Referring now to FIG. 16, a third structure 216 is attached to the second structure 214 by a conductive adhesive, solder, or a combination of a conductive adhesive or solder with a non-conductive adhesive (not shown). The third structure 216 is provided as a lid of the package 200. The third structure 216 is similar to the first structure 212 and may utilize one or multiple layers. For example, the lid 216 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. As mentioned earlier, the third structure 216 may integrate with the second structure 214 as a single structure to form a cap with four side walls and the first structure 212 as a base is attached to the cap, defining a housing 211. A second housing may be added to couple with the first housing 211 in back-to-back alignment to form a stacked package. The housing 211 protects the microphone 222 and the IC 224 from light, EMI, and physical damage.

Referring now to FIG. 17, the package 200 is then mounted on an optional dicing tape 228 and subsequently diced along a dicing street 230 to produce a plurality of packages. Alternatively, the package 200 may be held by a vacuum and then singulated into a plurality of packages. The layer of dicing tape 228 may have a UV releasable adhesive. Other examples of tapes are possible. The dicing occurs through the housing 211 and through the protective coating 220 disposed within the housing 211, but the tape 228 is not cut through to produce cuts or saw kerfs 232, as shown in FIG. 18. The dicing may be realized by using a saw, a laser, scribing or breaking. Other examples of dicing processes are possible.

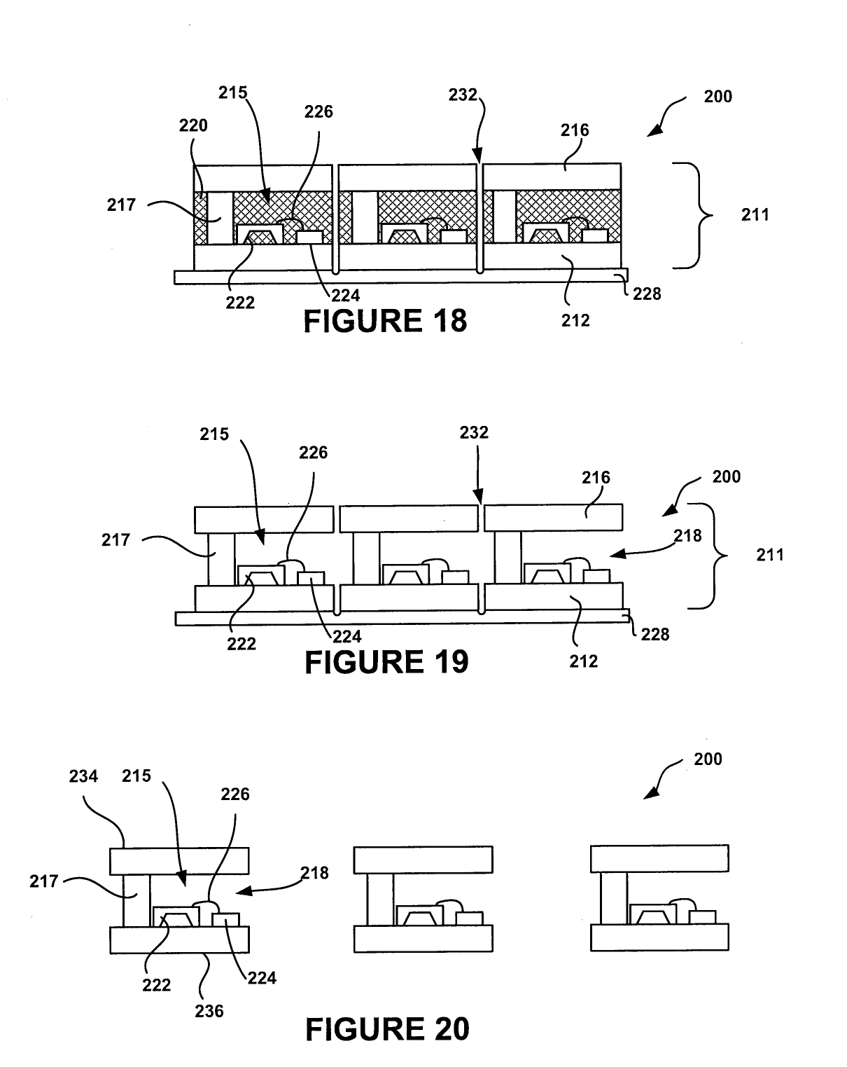

Now, as illustrated in FIG. 19, while the packages 200 are still remaining on the tape 228, the packages 200 are then transferred as is to a chamber (not shown) and cured at a temperature for a certain period until the protective coating 220 is completely removed from the cavity 215 of the housing 211. A port 218 is formed on the side wall adjacent to connecting walls 234, 236 of the housing 211 allowing the acoustic signals into the cavity 215 to interact with the microphone 222 mounted within the housing 211. One advantage of the package 200 is that, unlike the conventional packages, the port 218 of the package 200 is not formed by mechanically punched hole or drilled through the structures 212, 214, or 216. Dicing the housing 211 and then subsequently curing the protective coating 220 to form the port 218 for the purpose of providing sound path leading to the dies 222, 224 disposed within the housing 211 simplifies the manufacturing process. Further, the manufacturing costs are reduced and reliability is enhanced.

As illustrated in FIG. 20, the packages 200 together with the tape 228 are exposed by UV radiation (not shown). This exposure to the radiation is sufficient to break the bond between the tape 228 and the packages 200. Alternatively, the packages 200 can be released from the tape 228 using eject needles or a combination of UV, heat, eject needles, or other release techniques. Individual packages 200 are then lifted off from the tape 228 with die sorting equipment (not shown) ready for inspection, testing, or actual use.

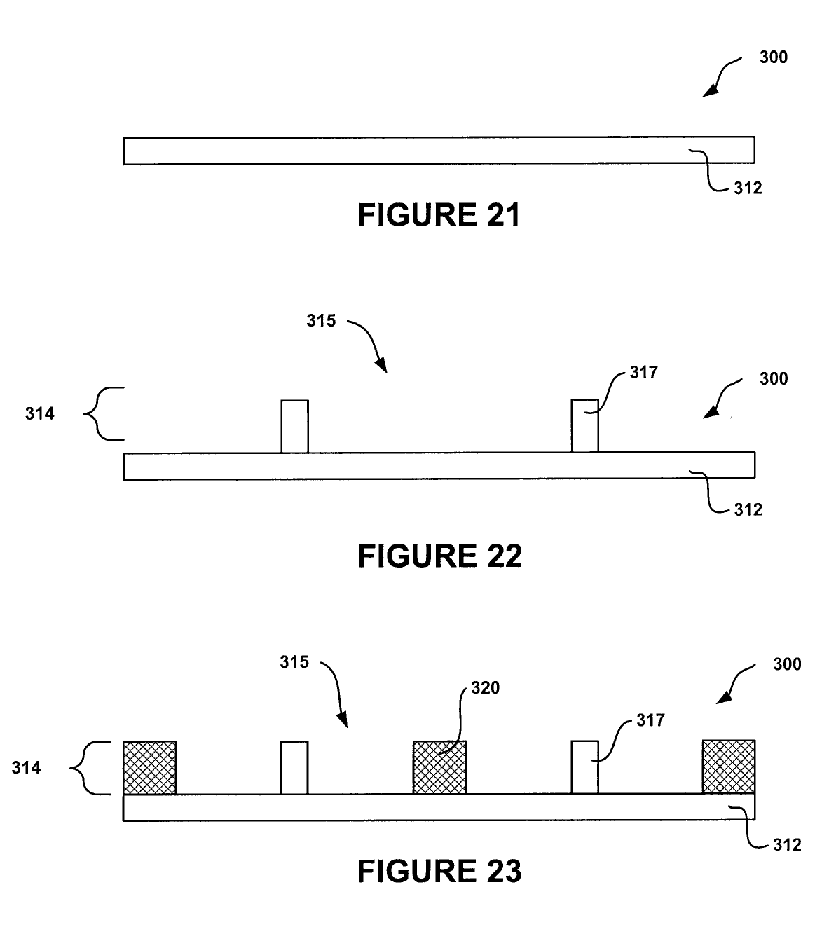

FIGS. 21-29 illustrate one process of forming an acoustic port 318 during a separation process. FIGS. 21-29 are similar in construction to the package 200 in FIGS. 12-20 and like elements are identified with a like reference convention wherein, for example, element 212 corresponds to element 312. As illustrated in FIG. 21, a first structure 312 is provided as a base of the package 300. The base 312 can be formed from a printed circuit board (PCB), a flexible circuit, a ceramic substrate, a thin film multichip module substrate, or similar substrate material. The base 312 may be a rigid or flexible support for embedded electronic components. The base 312 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating.

Referring now to FIG. 22, a second structure 314 is attached to the first structure 312 by a conductive adhesive, solder, or a combination of a conductive adhesive or solder with a non-conductive adhesive (not shown). The second structure 314 is provided as a spacer having a cavity 315 surrounded by side walls 317. The spacer 314, which may be the same material as the first structure 312, may utilize one or multiple layers. For example, the spacer 314 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic.

As shown in FIG. 23, a portion of the cavity 315 is filled or covered by a protective coating 320 using evaporation, condensation, spin coating, spraying, brushing, flow coating, or screen printing, depending on the desired applications to protect the die and the electronic device from shock, stress, and debris during dicing process. Other techniques may also be used. The protective coating 320 may be a water insoluble coating, although depending on the dicing method and whether it employs water-jets, water soluble coatings may be used. The protective coating 320 may be chosen from a set of materials that are in soft solid form, high vapor pressure or decomposition temperature near 150 degrees Celsius, no residue after removal, no tendency to create stiction. In one embodiment the protective coating 320 may be a polynorbornene (PNB) material, commonly available under the trade designation Unity from Promerus, LLC, or of any similar materials. Generally, this material may be applied as a liquid and cured to a solid with heat. Decomposition typically occurs at an elevated temperature range between 200° C. and 425° C. Alternatively, the protective coating 320 material may be chosen from a set of materials that can be evaporated or sublimated off the wafer for removal. One set of materials includes linear carbon chain molecules containing 12-18 carbon atoms. For example, the protective coating 320 may be Dodecanol, Heptadecanal, Heptadecanol, or chlorinated materials such as 2,6-dichloro-2,6-dimethylheptane. In one preferred embodiment, the protective coating 320 is Cetyl alcohol CH₃(CH₂)₁₅ OH also known as 1-Hexadecanol with a melting point greater than 24° C. and preferably less than 50° C., and a boiling point greater than 100° C. and preferably less than 150° C.

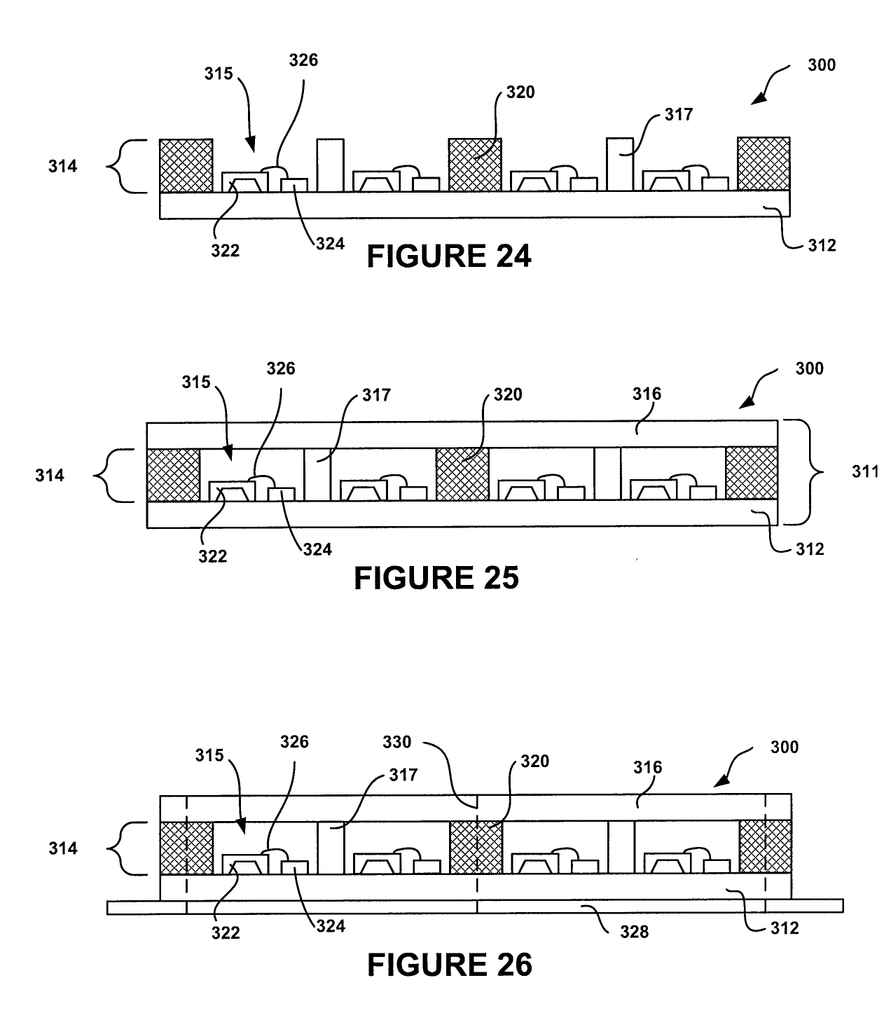

Now, as illustrated in FIG. 24, a MEMS die 322 and an electronic device 324 are disposed within the cavity 315 of the package 300. The MEMS die 322 is attached to the first structure 312 with an adhesive (not shown). For example, the electronic device 324 may be an IC that is attached to the first structure 312 with an adhesive (not shown). Alternatively, the electronic device 324 may be a passive component that is attached to the first structure 312 by a surface mounting technique (SMT). In one embodiment, the electronic device 324 is the IC and the MEMS die 322 is a microphone. The IC die 324 is then wire-bonded by wires 326 to the microphone 322 to a bond pad (not shown) on the microphone 322 and to a bond pad (not shown) on the first structure 312. The IC 324 and the microphone 322 may be integrated into a single chip that is attached to the first structure 312 using an adhesive in a die-attach process.

Referring now to FIG. 25, a third structure 316 is attached to the second structure 314 by a conductive adhesive, solder, or a combination of a conductive adhesive or solder with a non-conductive adhesive (not shown). The third structure 316 is provided as a lid of the package 300. The third structure 316 is similar to the first structure 312 and may utilize one or multiple layers. For example, the lid 316 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. As mentioned earlier, the third structure 316 may integrate with the second structure 314 as a single structure to form a cap with four side walls and the first structure 312 as a base that is attached to the cap, defining a housing 311. A second housing may be added to couple with the first housing 311 in back-to-back alignment to form a stacked package. The housing 311 protects the microphone 322 and the IC 324 from light, EMI, and physical damage.

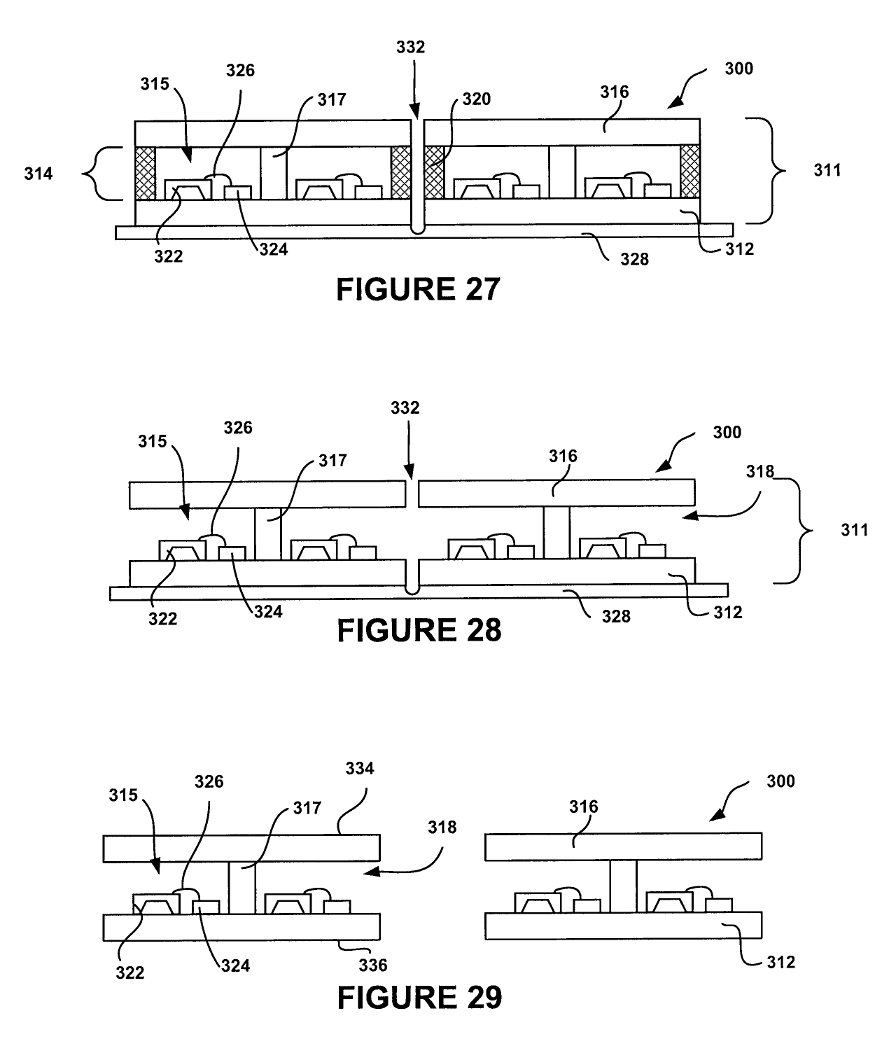

Referring now to FIG. 26, the package 300 is then mounted on an optional dicing tape 328 and subsequently diced along a dicing street 330 to produce a plurality of dual packages. Alternatively, the package 300 may be held by a vacuum and then singulated into a plurality of packages. The layer of dicing tape 328 may have a UV releasable adhesive. Other examples of tapes are possible. As depicted in FIG. 27, the dicing occurs through the housing 311 and through the protective coating 320 disposed within the housing 311, but the tape 328 is not cut through to produce cuts or saw kerfs 332 to form a dual package 300. The dicing may be realized by using a saw, a laser, scribing or breaking. Other examples of dicing processes are possible.

Now, as illustrated in FIG. 28, while the packages 300 are still remaining on the tape 328, the packages 300 are then transferred as is to a chamber (not shown) and cured at a temperature for a certain period until the protective coating 320 is completely removed from the housing 311. Ports 318 are formed on the side wall adjacent to connecting walls 334, 336 of the housing 311 allowing the acoustic signals into the cavity 315 to interact with the microphones 322 mounted within the housing 311. One advantage of the dual package 300 is that, unlike the conventional packages, the ports 318 of the package 300 are not formed by mechanically punched hole or drilled through the housing 311. Dicing the housing 311 and then subsequently curing the protective coating 320 to form the ports 318 for the purpose of providing sound path leading to the dies 322, 324 disposed within the housing 311 simplify the manufacturing process. Further, the manufacturing costs are reduced and reliability is enhanced.

Finally, as shown in FIG. 29, the dual packages 300 together with the tape 328 are exposed by UV radiation (not shown). This exposure to the radiation is sufficient to break the bond between the tape 328 and the packages 300. Alternatively, the packages 300 can be released from the tape 328 using eject needles or a combination of UV, heat, eject needles, or other release techniques. Individual packages 300 are then lifted off from the tape 328 with die sorting equipment (not shown) ready for inspection, testing, or actual use.

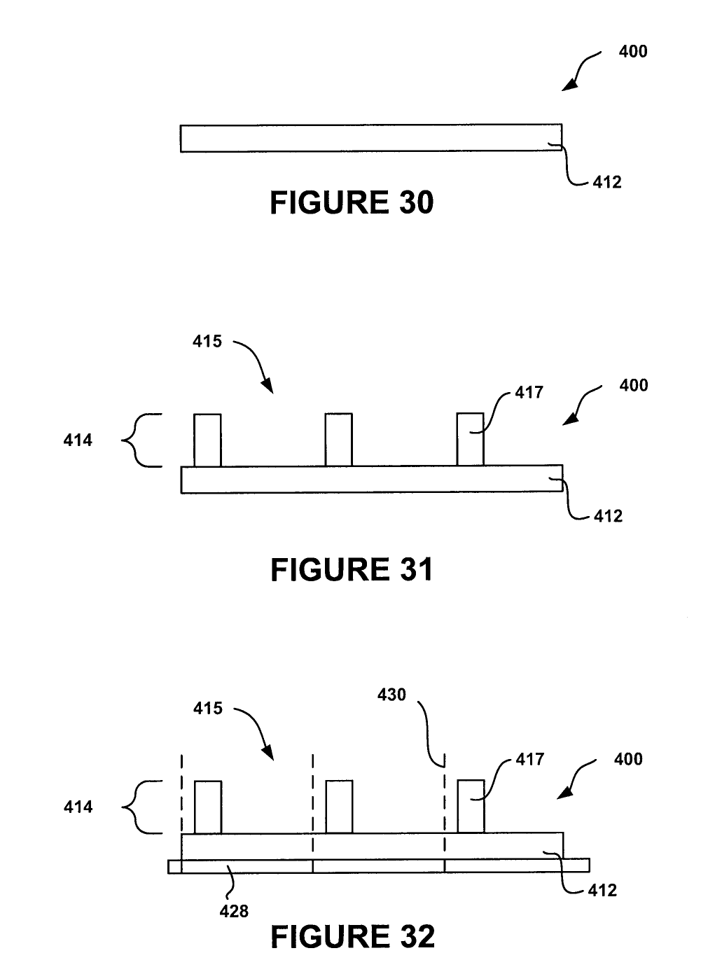

FIGS. 30-36 illustrate one process of forming an acoustic port 418 during a separation process. FIGS. 30-36 are similar in construction to the package 300 in FIGS. 21-29 and like elements are identified with a like reference convention wherein, for example, element 312 corresponds to element 412. As illustrated in FIG. 30, a first structure 412 is provided as a base of the package 400. The base 412 can be formed from a printed circuit board (PCB), a flexible circuit, a ceramic substrate, a thin film multichip module substrate, or similar substrate material. The base 412 may be a rigid or flexible support for embedded electronic components. The base 412 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating.

Referring now to FIG. 31, a second structure 414 is attached to the first structure 412 by a conductive adhesive, solder, or a combination of a conductive adhesive or solder with a non-conductive adhesive (not shown). The second structure 414 is provided as a spacer having a cavity 415 surrounded by side walls 417. The spacer 414, which may be the same material as the first structure 412, may utilize one or multiple layers. For example, the spacer 414 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The second structure 414 may integrate with the first structure 412 as a single structure to form a base housing with four side walls.

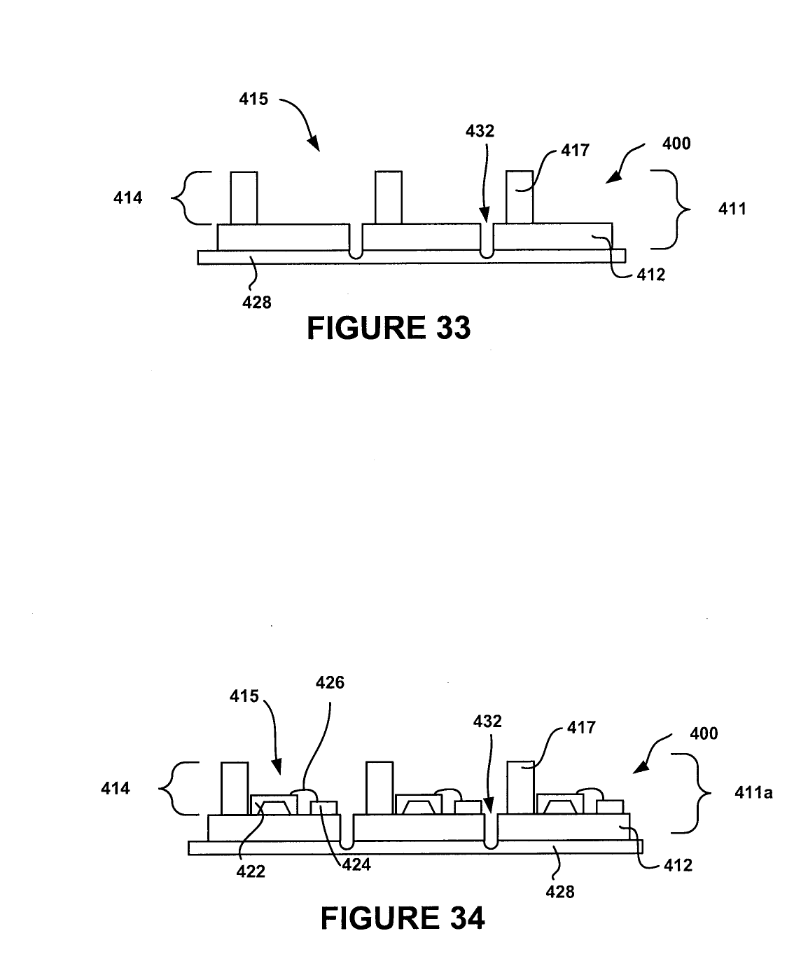

As shown in FIG. 32, the bottom surface of the first structure 412 is then mounted on a dicing tape 428 and subsequently diced along a dicing street 430 to produce a plurality of base housings 411a as shown in FIG. 33. The layer of dicing tape 428 may have a UV releasable adhesive. Other examples of tapes are possible. As depicted in FIG. 33, the dicing occurs through the base housings 411a but the tape 428 is not completely cut through to produce cuts or saw kerfs 432. The dicing may be realized by using a saw, a laser, scribing or breaking. Other examples of dicing processes are possible.

Now, as illustrated in FIG. 34, a MEMS die 422 and an electronic device 424 are disposed within the cavity 415 of the base housing 411a. The MEMS die 422 is attached to the first structure 412 with an adhesive (not shown). For example, the electronic device 424 may be an IC that is attached to the first structure 412 with an adhesive (not shown). Alternatively, the electronic device 424 may be a passive component that is attached to the first structure 412 by a surface mounting technique (SMT). In one embodiment, the electronic device 424 is the IC and the MEMS die 422 is a microphone. The IC die 424 is then wire-bonded by wires 426 to the microphone 422 to a bond pad (not shown) on the microphone 422 and to a bond pad (not shown) on the first structure 412. The IC 424 and the microphone 422 may be integrated into a single chip that is attached to the first structure 412 using an adhesive in a die-attach process.

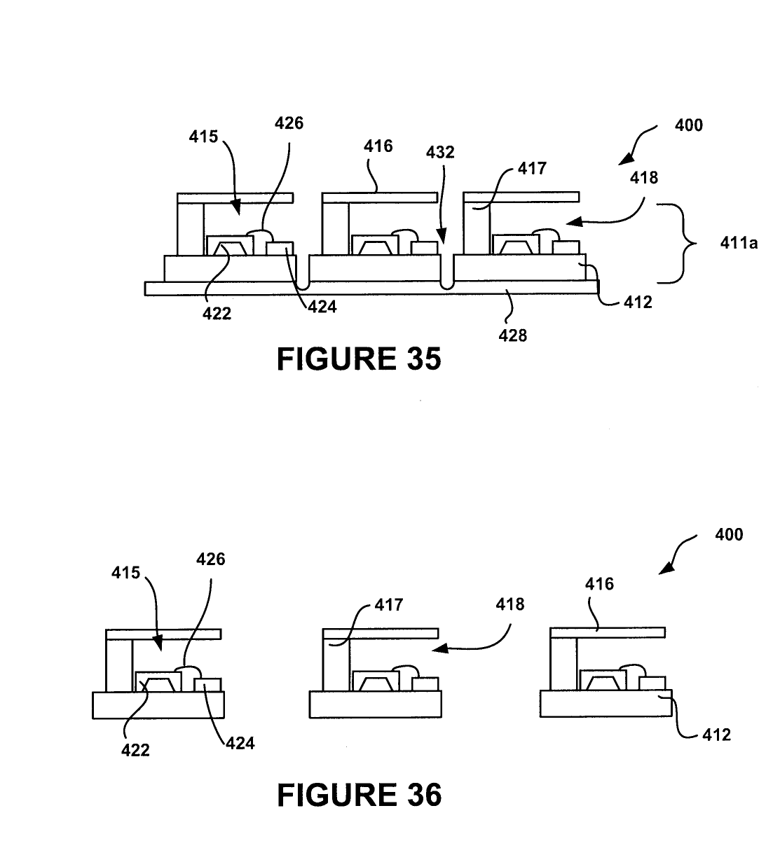

While the base housings 411a still remaining on the tape 428, a plurality of lids 416 are attached to the base housing 411a using a conductive adhesive, solder, or a combination of a conductive adhesive or solder with a non-conductive adhesive (not shown), defining a package housing 411 as shown in FIG. 35. The lids 416 are similar to the base 412 and may utilize one or multiple layers. For example, the lids 416 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The housing 411 protects the dies 422, 424 from light, EMI, and physical damage. Ports 418 are formed on the side wall of the housing 411 allowing the acoustic signals into the cavity 415 to interact with the microphones 422 mounted within the housing 411. One advantage of the package 400 is that, unlike the conventional packages, the ports 418 of the package 400 are not formed by mechanically punching hole or drilling through the housing 411. Dicing the housing 411 to form the ports 418 simplify the manufacturing process. Further, the manufacturing costs are reduced and reliability is enhanced.

Now, as illustrated in FIG. 36, the packages 400 together with the tape 428 are exposed by UV radiation (not shown). This exposure to the radiation is sufficient to break the bond between the tape 428 and the packages 400. Alternatively, the packages 400 can be released from the tape 428 using eject needles or a combination of UV, heat, eject needles, or other release techniques. Individual packages 400 are then lifted off from the tape 428 with die sorting equipment (not shown) ready for inspection, testing, or actual use.

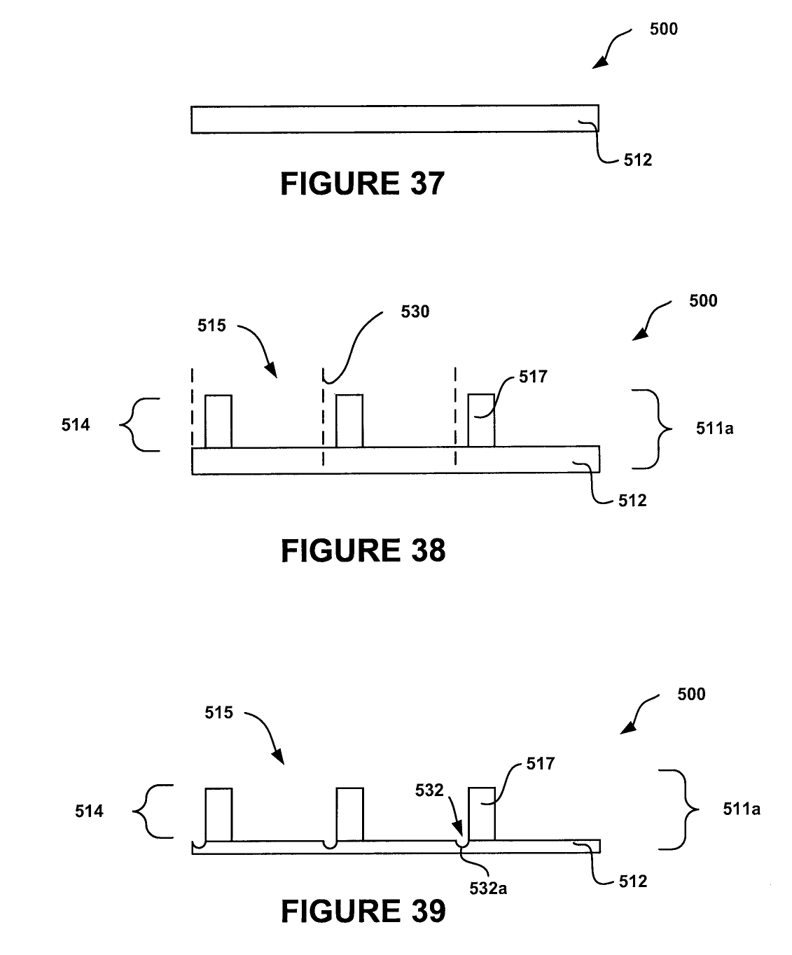

FIGS. 37-42 illustrate one process of forming an acoustic port 518 during a separation process. FIGS. 37-42 are similar in construction to the package 400 in FIGS. 30-36 and like elements are identified with a like reference convention wherein, for example, element 412 corresponds to element 512. As illustrated in FIG. 37, a first structure 512 is provided as a base of the package 500. The base 512 can be formed from a printed circuit board (PCB), a flexible circuit, a ceramic substrate, a thin film multichip module substrate, or similar substrate material. The base 512 may be a rigid or flexible support for embedded electronic components. The base 512 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating.

Referring now to FIG. 38, a second structure 514 is attached to the first structure 512 by a conductive adhesive, solder, or a combination of a conductive adhesive or solder with a non-conductive adhesive (not shown). The second structure 514 is provided as a spacer having a cavity 515 surrounded by side walls 517. The spacer 514, which may be the same material as the first structure 512, may utilize one or multiple layers. For example, the spacer 514 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The second structure 514 may integrate with the first structure 512 into a single structure to form a base housing 511a with four side walls 517. A plurality of dicing streets 530 are formed on the base housing 511a for partial dicing.

Referring now to FIG. 39, the base housing 511a is diced along a dicing street 530 to produce a plurality of base housings 511a. The dicing occurs through the second structure 514 but the first structure 512 is not completely cut through to produce cuts or saw kerfs 532. The dicing may be realized by using a saw, a laser, scribing or breaking. Other examples of dicing processes are possible. Because the first structure 512 is not completely cut through, a supportive web 532a is formed to hold the individual base housings 511a in a fixed position spaced apart from the supportive web.

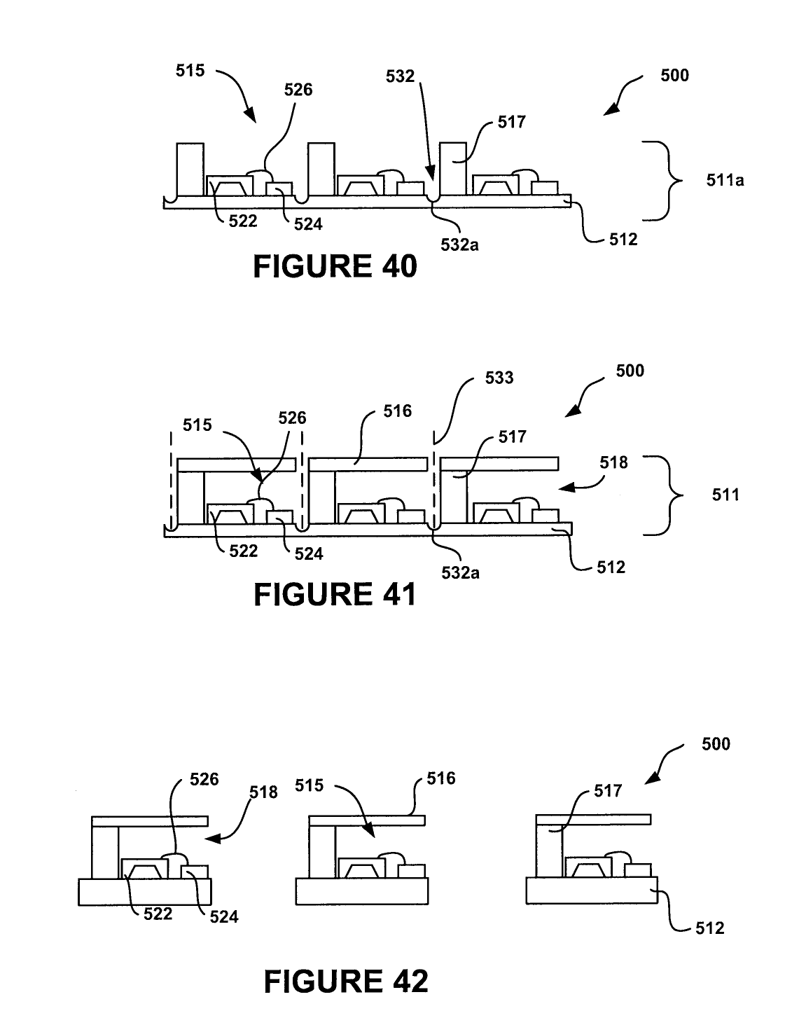

Now, as illustrated in FIG. 40, a MEMS die 522 and an electronic device 524 are disposed within the cavity 515 of the base housing 511a. The MEMS die 522 is attached to the first structure 512 with an adhesive (not shown). For example, the electronic device 524 may be an IC that is attached to the first structure 512 with an adhesive (not shown). Alternatively, the electronic device 524 may be a passive component that is attached to the first structure 512 by a surface mounting technique (SMT). In one embodiment, the electronic device 524 is the IC and the MEMS die 522 is a microphone. The IC die 524 is then wire-bonded by wires 526 to the microphone 522 to a bond pad (not shown) on the microphone 522 and to a bond pad (not shown) on the first structure 512. The IC 524 and the microphone 522 may be integrated into a single chip that is attached to the first structure 512 using an adhesive in a die-attach process.

As shown in FIG. 41, a plurality of lids 516 are attached to the base 512 using a conductive adhesive, solder, or a combination of a conductive adhesive or solder with a non-conductive adhesive (not shown), defining a package housing 511. The lids 516 are similar to the base 512, may utilize one or multiple layers. For example, the lids 516 may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The housing 511 protects the dies 522, 524 from light, EMI, and physical damage. A second plurality of dicing streets 533 (See FIG. 41) along the housing 511 are introduced to completely separate the housing 511 into individual packages 500.

Now, as illustrated in FIG. 42, ports 518 are formed on the side wall of the housing 511 allowing the acoustic signals into the cavity 515 to interact with the microphones 522 mounted within the housing 511. One advantage of the package 500 is that, unlike the conventional packages, the ports 518 of the package 500 are not formed by mechanically punching hole or drilling through the housing 511. Dicing the housing 511 to form the ports 518 simplify the manufacturing process. Further, the manufacturing costs are reduced and reliability is enhanced. Finally, individual packages 500 are then ready for inspection, testing, or actual use.

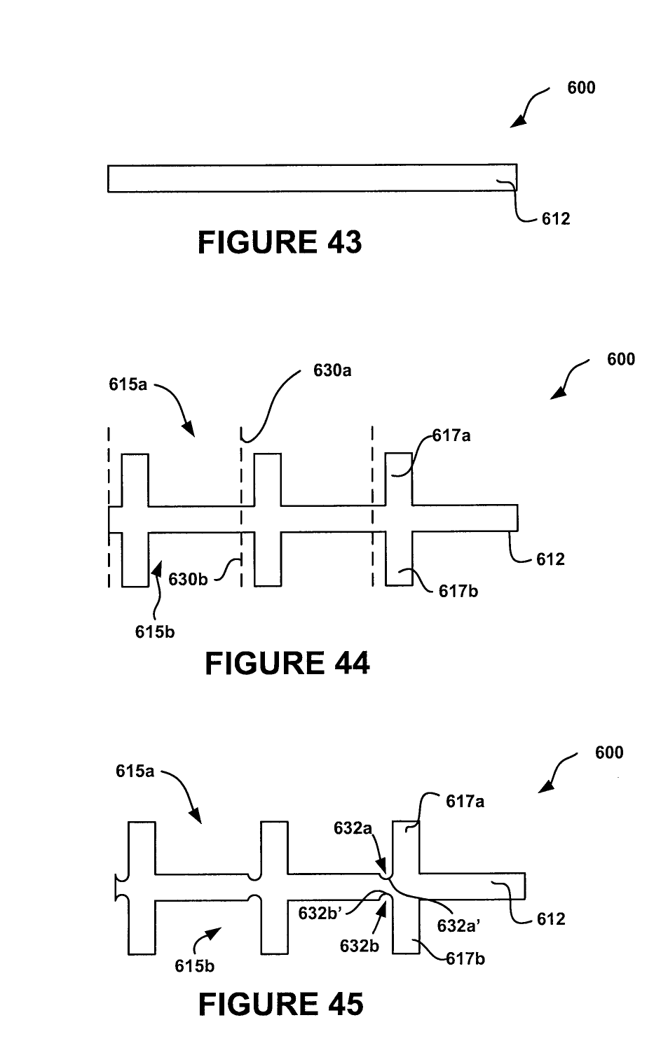

FIGS. 43-48 illustrate one process of forming an acoustic port 618 during a separation process. FIGS. 43-48 are similar in construction to the package 400 in FIGS. 37-42 and like elements are identified with a like reference convention wherein, for example, element 512 corresponds to element 512. As illustrated in FIG. 43, a first structure 612 is provided as a base of the package 600. The base 612 can be formed from a printed circuit board (PCB), a flexible circuit, a ceramic substrate, a thin film multichip module substrate, or similar substrate material. The base 612 may be a rigid or flexible support for embedded electronic components. The base 612 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating. As shown in FIG. 44, the base 612 comprises a first cavity 615a and a second cavity 615b opposed to the first cavity 615a. The base 612 further comprises a first side wall 617a and a second side wall 617b opposed to the first side wall 617a. Base 612 is partially diced along dicing streets 630a, 630b to form a plurality of base housings as shown in FIG. 45.

Referring now to FIG. 45, the base 612 is partially diced along dicing streets 630a, 630b. The first dicing occurs by partially cut through the first surface of the base 612 along the dicing street 630a to produce cuts or saw kerfs 632a. The second dicing occurs by partially cut through the second surface of the base 612 along the dicing street 630b to produce cuts or saw kerfs 632b. Alternatively, only one dicing occurs on either the first or second surface of the base 612 as long as at least one support web 632a′ or 632b′ is formed on one of the surface of the base to hold the individual base housings 611 in a fixed position spaced apart from the support web 632a′ or 632b′. The dicing may be realized by using a saw, a laser, scribing or breaking. Other examples of dicing processes are possible.

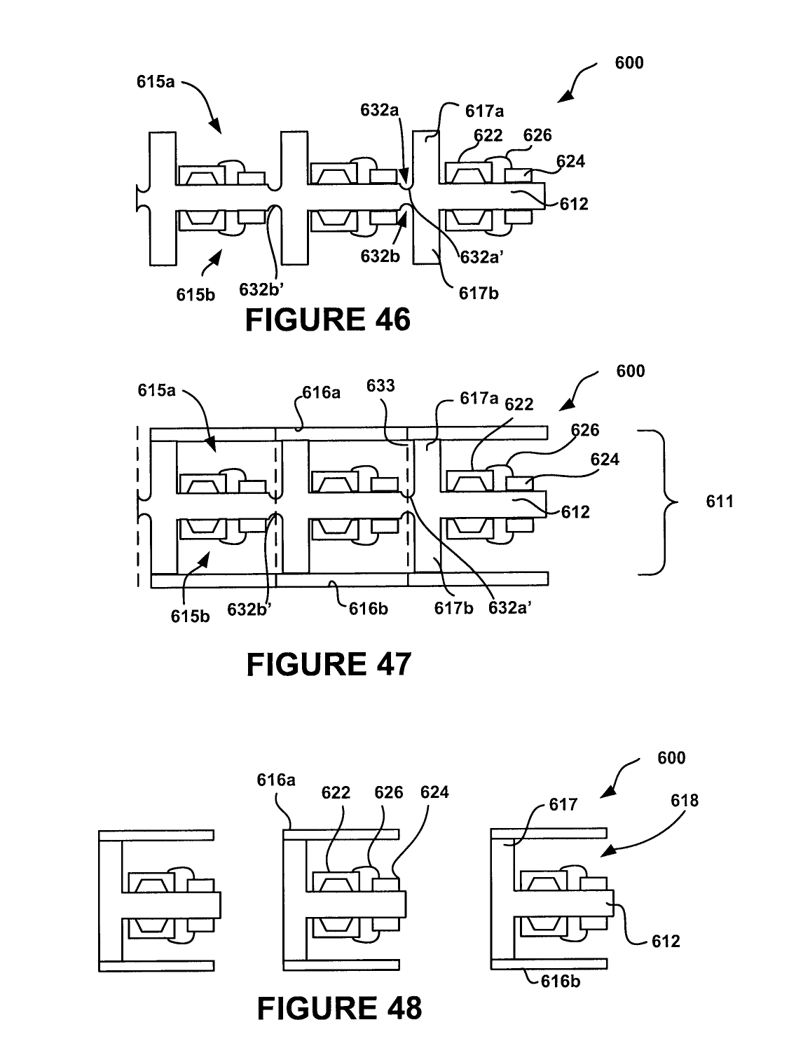

Now, as illustrated in FIG. 46, a MEMS die 622 and an electronic device 624 are disposed within the cavities 615a, 615b of the base 612. The MEMS die 622 is attached to the first and second surfaces of the base 612 with an adhesive (not shown). For example, the electronic device 624 may be an IC is attached to the first and second surfaces of the base 612 with an adhesive (not shown). Alternatively, the electronic device 624 may be a passive component is attached to the first and second surfaces of the base 612 by a surface mounting technique (SMT). In one embodiment, the electronic device 624 is the IC and the MEMS die 622 is a microphone. The IC die 624 is then wire-bonded by wires 626 to the microphone 622 to a bond pad (not shown) on the microphone 622 and to a bond pad (not shown) on the first and second surfaces of the base 612. The IC 624 and the microphone 622 may be integrated into a single chip is attached to the first structure 612 using an adhesive in a die-attach process.

As shown in FIG. 47, a second structure 616a is attached to the side walls 617a of the base 612 and a third structure 616b is attached to the side walls 617b of the base 612 using a conductive adhesive, solder, or a combination of a conductive adhesive or solder with a non-conductive adhesive (not shown), defining a package housing 611. The second and third structures 616a, 616b are provided as lids. Like the first structure 612, the second and third structures 616a, 616b may utilize one or multiple layers. For example, the lids 616a, 616b may be constructed by forming alternating layers of conductive and non-conductive materials and the layers are joined together using adhesive or adhesive-less laminating techniques. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The packaging housing 611 protects the dies 622, 624 from light, EMI, and physical damage. A third plurality of dicing streets 633 along the housing 611 are introduced to completely separate the housing 611 into individual stacked packages 600.

Now, as illustrated in FIG. 48, ports 618 are formed on the side wall of the housing 611 allowing the acoustic signals into the cavity 615a, 615b to interact with the microphones 622 mounted within the housing 611. One advantage of the stacked package 600 is that, unlike the conventional packages, the ports 618 of the package 600 are not formed by mechanically punching hole or drilling through the housing 611. Dicing the housing 611 to form the ports 618 simplify the manufacturing process. Further, the manufacturing costs are reduced and reliability is enhanced. Finally, individual stacked packages 600 are then ready for inspection, testing, or actual use.

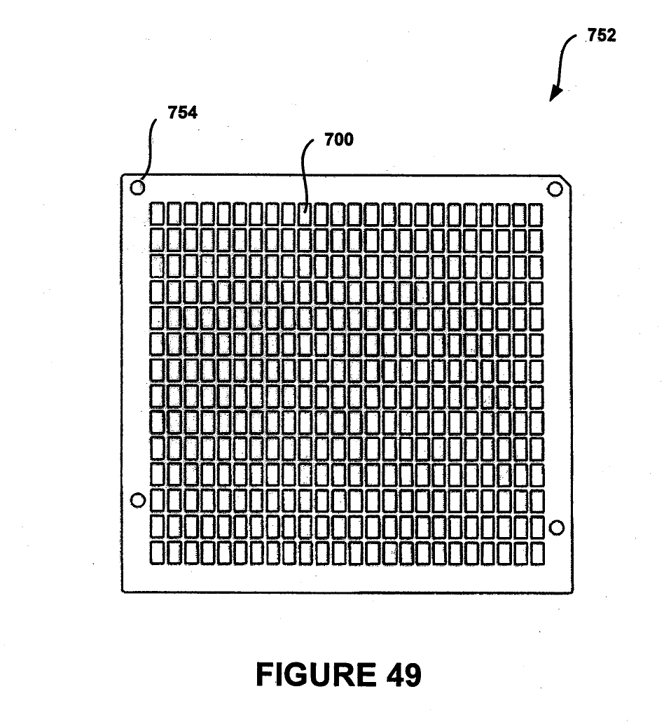

FIG. 49 is a plan view illustrating a panel 752. The panel 752 comprises a plurality of alignment apertures 754 to ensure proper placement and alignment of the panel 752 when more than one panel are assembled together to form a plurality of packages 700. The panel 752 may be a base housing, a top housing, a combination of base with sidewalls, or a combination of top housing with sidewalls.

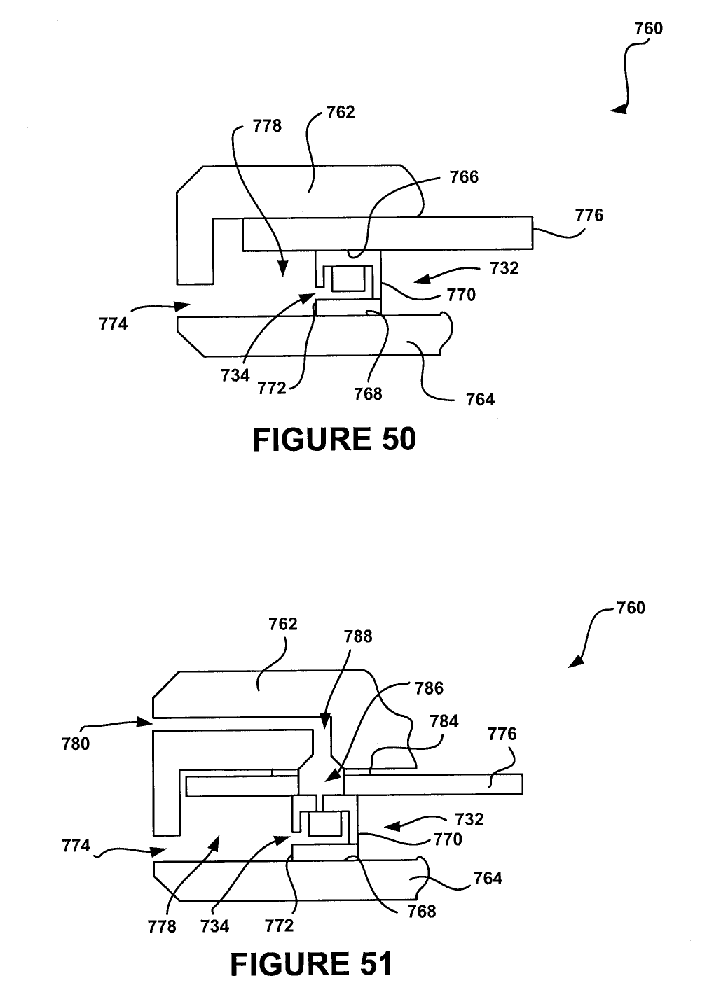

FIGS. 50-52 and 63 illustrate an electronic device 760 incorporating a transducer package 732. The electronic device 760 may be a web-enabled phone, a cellular phone, a personal digital assistant (PDA) device, a laptop, a pager, a digital camera, a listening device, a hearing aid and the like. In the embodiments, the electronic device 760 is a cellular phone. The device 760 comprises a housing having a top housing 762 and a bottom housing 764 joined to the top housing 762 by any suitable methods of attachment, including mechanical fastening, crimping, welding, or adhesive bonding, and the like. At least one sound opening 774 is introduced on the surface of the housing to allow acoustic waves to enter or exit. A printed circuit bond (PCB) 776 is included in the device 760 that includes electrical and other components that are used during the operation of the device 760. At least one connecting surface (four are illustrated as 766, 768, 770, 772) of the package 732 is introduced for connecting with the inner walls of the top and bottom housings 762, 764, the PCB 776, or combination thereof. As shown in FIG. 50, the connecting surface 766 is electrically connected to a first surface of the PCB 776 via a soldering process; however, it will be understood by those skilled in the art that any form of electrical connect in would suffice, including conductive adhesive, contacts, spring-loaded contacts, plug, and the like. A second surface of the PCB 776 opposed to the first surface is coupled to the inner wall of the top housing 762. The connecting surface 768 of the package 732 is coupled to the inner wall of the bottom housing 764. A cavity 778 is formed within the device 760 to acoustically couple the sound opening 774 of the device 760 to an acoustic port 734 of the package 732 via the cavity 778. The cavity 778 may be a back volume, a front volume, a mixed volume, or a recess. In this embodiment, the cavity 778 is a front volume. Other types of cavities are possible.

As depicted in FIG. 51, an acoustic seal 784 is provided to seal the top housing 762 to the PCB 776. A second sound opening 780 is introduced on the surface of the housing 762 to allow acoustic waves to enter or exit. An aperture 786 is formed within the PCB 776 to acoustically couple the second sound opening 780 to the aperture 786 via a second cavity 788 formed between the top housing 762 and the PCB 726. A second optional acoustic port (not shown) is formed within the package 732 to provide directional characteristics.

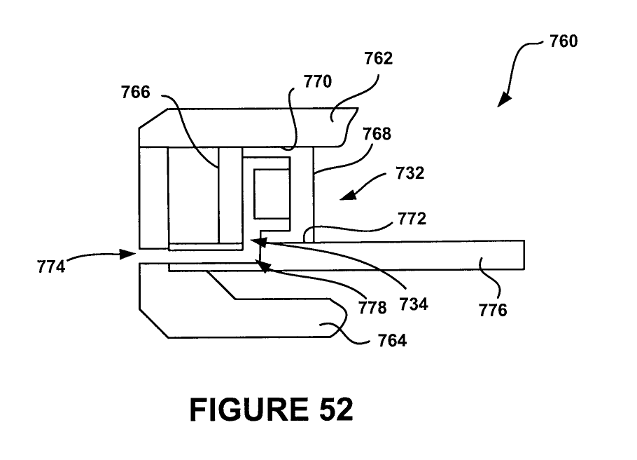

Now, referring to FIG. 52, the connecting wall 770 of the package 732 is attached to the inner wall of the top housing 762 by any known techniques. The connecting wall 772 of the package 732 where the port 734 is located is attached to the top surface of the PCB 776. A cavity 778 is formed within the PCB 776 by any known techniques is acoustically coupled to the port 734 of the package 732. A sound opening 774 of the device 760 is introduced allowing the acoustic waves to enter into the cavity 778 and interact with the die formed within the package 732.

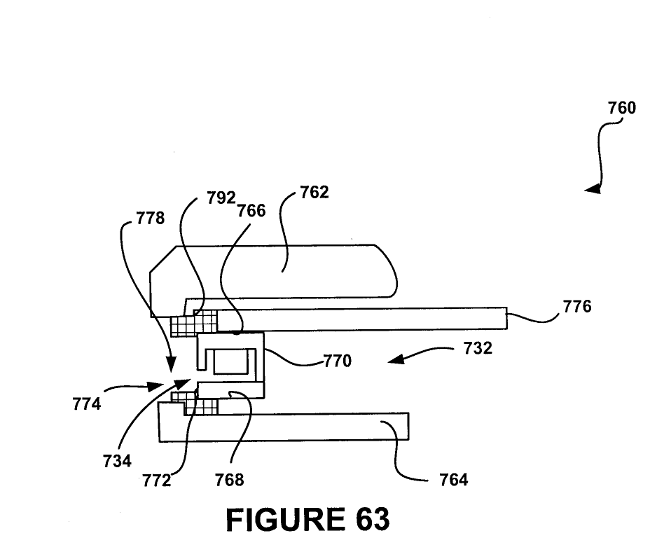

Referring now to FIG. 63, a gasket 792 is provided within the device 760 to serve as an acoustic seal. The package 732 is attached to the PCB 776 and a surface of the gasket 792. The gasket 792 may be formed as a portion of the device housing comprises an opening 774 to allow acoustic signals to enter and interact with the die disposed within the package 732. Alternatively, the gasket 792 may be formed as a portion of the package 732.

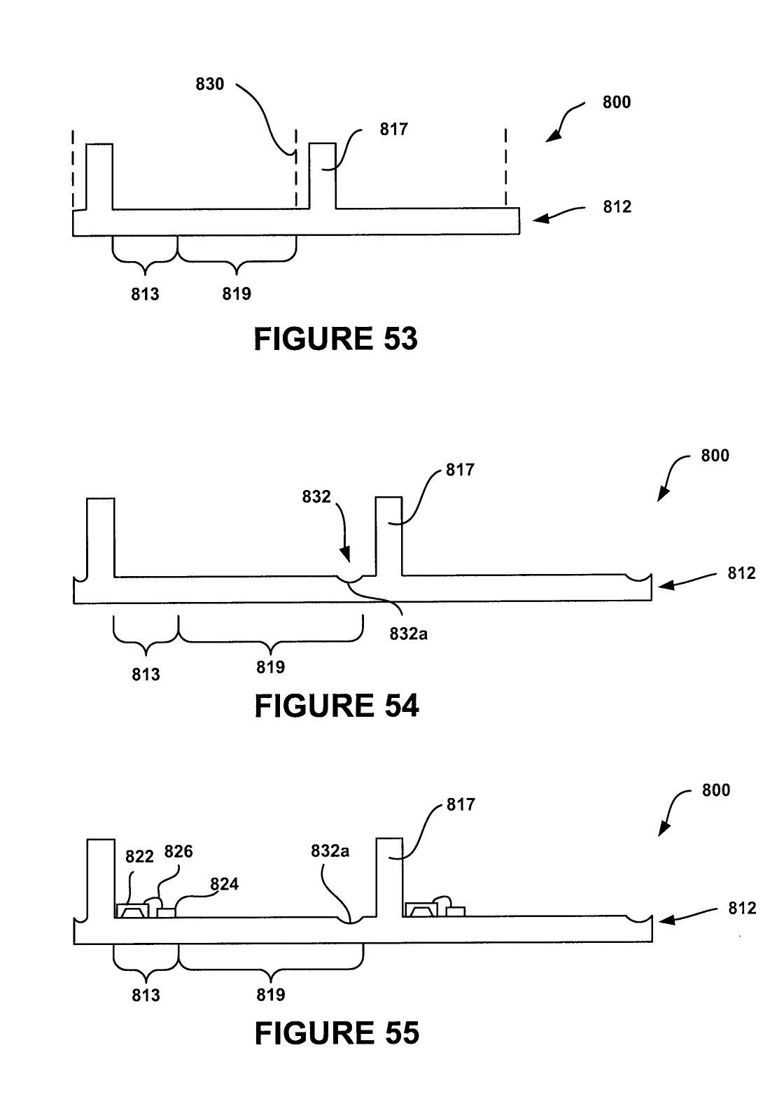

FIGS. 53-59 illustrate one process of forming an acoustic port 818 during a separation process. FIGS. 53-59 are similar in construction to the package 500 in FIGS. 37-42 and like elements are identified with a like reference convention wherein, for example, element 512 corresponds to element 812. As illustrated in FIG. 53, a structure 812 comprises a base portion 813, sidewalls 817, and an elongated portion 819. The structure 812 can be formed from a printed circuit board (PCB), a flexible circuit, a ceramic substrate, a thin film multichip module substrate, or a rigid substrate, a foldable substrate, a combination thereof, or similar substrate material. The structure 812 may be a rigid or flexible support for embedded electronic components. The structure 812 may be made of conductive material, non-conductive material, or combination thereof. The conductive material may be copper, a copper alloy, an aluminum alloy, a polymer conductive adhesive (PCA) or alloy and combination thereof. The non-conductive material may be Flame Retardant woven glass reinforced epoxy resin (FR-4), rubber, polyimide, polyethylene polyimide (PEI), polyethtrafluoroethylene (PTFE), liquid crystal polymer (LCP), or plastic. The alternating conductive and non-conductive layers are joined together using adhesive or adhesive-less laminating techniques. Other suitable methods of attachment are sufficed such as vapor deposition, sputtering, evaporation, coating, electrodeposition, or plating. A plurality of dicing streets 830 are formed on the structure 812 for partial dicing.

A plurality of cuts or saw kerfs 832 are formed during dicing process but because the structure 812 is not completely cut through, a plurality of supportive webs 832a are formed as shown in FIG. 54. The dicing may be realized by using a saw, a laser, scribing or breaking. Other examples of dicing processes are possible. At least one folding line 842 (See FIG. 57) is formed on the structure 812 for folding process to form a housing 811. More details about the formation of the housing will follow.

Now, as illustrated in FIG. 55, a MEMS die 822 and an electronic device 824 are mounted on the top surface of the base portion 813. The MEMS die 822 is attached to the base portion 813 with an adhesive (not shown). For example, the electronic device 824 may be an IC that is attached to the base portion 813 with an adhesive (not shown). Alternatively, the electronic device 824 may be a passive component that is attached to the base portion 813 by a surface mounting technique (SMT). In one embodiment, the electronic device 824 is the IC and the MEMS die 822 is a microphone. The IC die 824 is then wire-bonded by wires 826 to the microphone 822 to a bond pad (not shown) on the microphone 822 and to a bond pad (not shown) on the base portion 813. The IC 824 and the microphone 822 may be integrated into a single chip that is attached to the base portion 813 using an adhesive in a die-attach process.

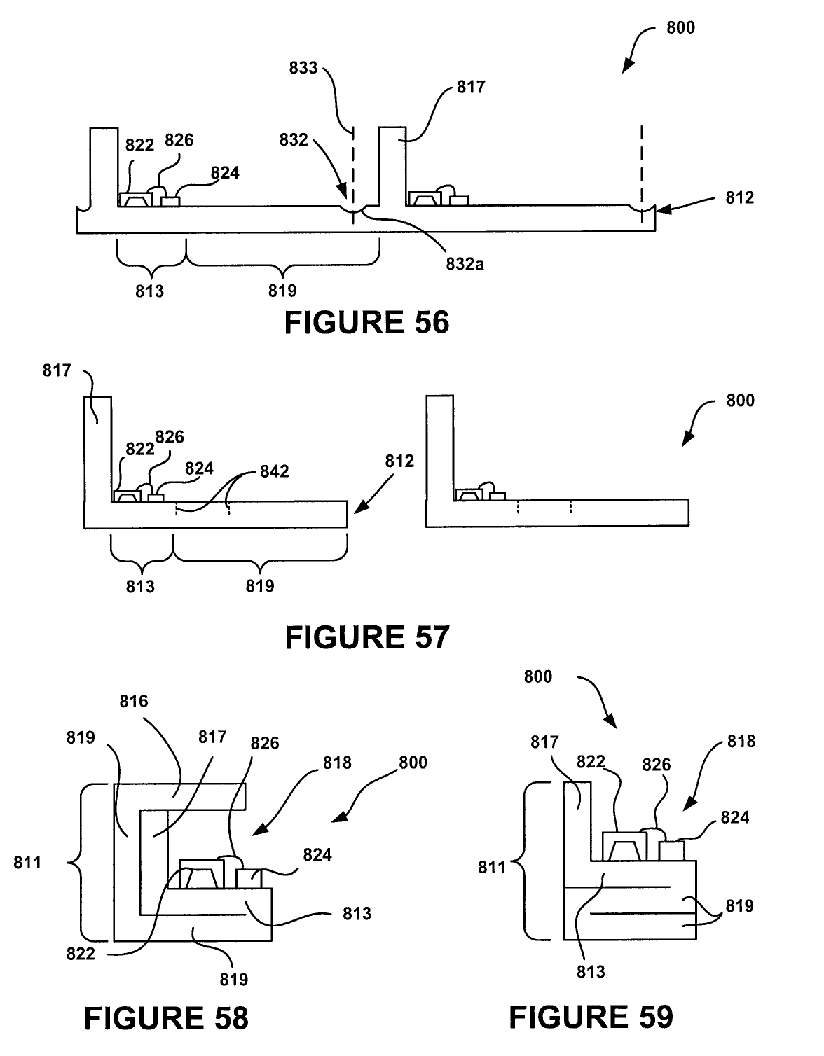

Referring now to FIG. 56, a second plurality of dicing streets 833 are introduced along the web 832a to singulate the structure 812 into individual packages 800 as shown in FIG. 57. As depicted in FIG. 58, the elongated portion 819 is folded along the folding line 842 to form a housing 811. A first section of the elongated portion 819 is folded such that the bottom surface of the first section is attached to the bottom surface of the base portion 813. A second section of the elongated portion 819 is folded to attach the bottom surface of the second portion to the outer surface of the sidewall 817. The remaining section of the elongated portion 819 is folded to form a lid 816 leaving a portion of the housing 811 opens. A port 818 is then formed on one side of the housing 811 allowing the acoustic waves to enter the housing 811 and interact with the dies 822, 824. The housing 811 protects the dies 822, 824 from light, EMI, and physical damage. Alternatively, the remaining portion of the elongated portion 819 terminates where the top portion of the sidewall 817 is located to form an opening 818. A multi-layer base portion 813 is formed by folding the elongated portion 819 at least once. The folded elongated portion 819 is attached to the bottom surface of the base portion 813. An opening 818 as shown in FIG. 59 having a dimension greater than the portion 818 as shown in FIG. 58 is formed allowing the acoustic waves to enter the housing 811. One advantage of the package 800 is that, unlike the conventional packages, a pre-punched opening on the structure 812 is not required to line up with the opening 818. Finally, individual packages 800 are then ready for inspection, testing, or actual use.

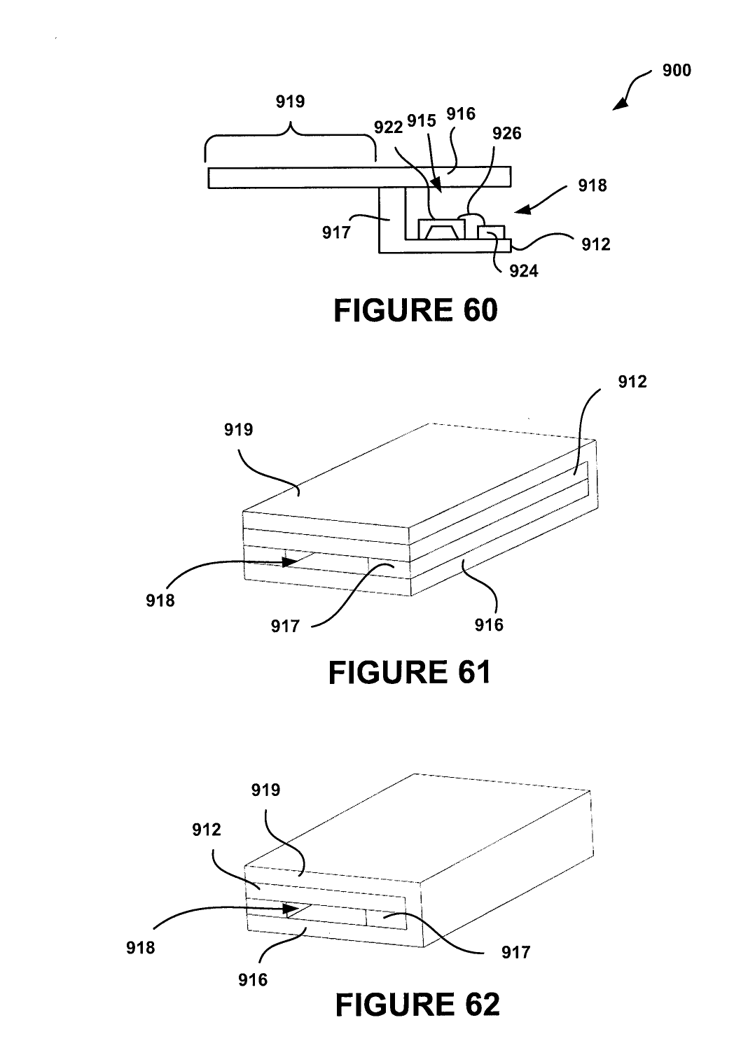

FIGS. 60-62 illustrate a folded package 900 incorporating a side port 918 formed during dicing process. FIGS. 60-62 are similar in construction to the foregoing packages and like elements are identified with a like reference convention. Only one package 900 is illustrated for simplicity. As shown in FIG. 60, a port 918 is formed after a first and second structures 912, 816 are diced into individual package 900. Alternatively, the second structure 916 is attached to the first structure 912 after the first structure 912 is singulated. The first structure 912 comprises a base with side walls 917 and at least one die 922 is mounted on the base of the first structure 912. A second structure 916 is attached to the side walls 917 of the first structure 912 to form a housing 911. The second structure 916 comprises a lid portion opposed to the base portion of the first structure 916 and an elongated portion 919 attached to the lid portion. At least one folding line (not shown) is formed on the elongated portion 919 to fold the elongated portion 919 in any desired shapes. At least a portion of the first structure 912 is covered by the folded elongated portion 919 leaving the side port 918 uncovered allowing the sound waves into the housing 911 to interact the die 922 mounted therein. As depicted in FIGS. 61-62, the first section of the elongated portion 919 adjacent to the lid 916 is folded downward such that the outer surface of one of the sidewall 917 is covered by and attached to the first section. A second section the elongated portion 919 is folded to attach the bottom surface of the base portion of the first structure 812. The end of the second section of the elongated portion 919 terminates where the side port 912 is located.

It will be appreciated that numerous variations to the above-mentioned approaches are possible. Variations to the above approaches may, for example, include performing the above steps in a different order. Further, more than one package may be mounted within a device. For example, a stacked package, a dual package, or a folded package, may be disposed within an electronic device. Packages utilizing the present approaches may be also used as electret-type transducer packages, optical packages, sensor packages and the like. Other types of usages and package types are possible. In another example, an optional terminal pad for coupling the packages to a PCB of any audio or communication devices may be formed on the first structure, the second structure, the third structure, a combination of at least two structures thereof. In yet another example, a laser dicing technique is used in the final step of the process to singulate the structure and to form a port, then partial dicing step is not required.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A method of forming a plurality of separate and distinct individual micro-electromechanical system (MEMS) packages comprising:
forming a plurality of individual MEMS packages as a contiguous unit, each of the plurality of individual MEMS packages including at least one acoustic port;
determining one or more separation boundaries from where to separate adjacent ones of the plurality of individual MEMS packages; and
subsequently separating each of the plurality of individual MEMS packages from the others according to the one or more separation boundaries to provide separate and distinct individual MEMS packages, wherein each acoustic port disposed within each separate and distinct individual MEMS package is exposed because of the separating so as to allow sound energy to enter each separate and distinct individual MEMS package.

2. The method of claim 1 further comprising mounting the contiguous unit on a mounting tape.

3. The method of claim 1 wherein separating comprises separating utilizing a process selected from a group consisting of sawing, laser cutting, scribing, and breaking.

4. The method of claim 1 further comprising at least partially applying a protective coating to each of the plurality of individual MEMS packages and subsequent to the separating, curing each of the separate and distinct individual MEMS packages to remove the coating.

5. The method of claim 1 wherein forming a plurality of individual MEMS packages comprises forming a base and a first structure attached to the base.

6. The method of claim 5 wherein each of the plurality of individual MEMS packages includes a cavity and wherein forming a plurality of individual MEMS packages comprises further disposing an electronic device and a MEMS die within the cavity of each of the plurality of individual MEMS packages and wherein the MEMS package is a package selected from a group consisting of a single MEMS package and a dual MEMS package.

7. A method of forming a micro-electromechanical system (MEMS) package comprising:
forming a MEMS package, the MEMS package including an elongated base;
disposing at least one MEMS device onto the base;
folding a first portion of the base to at least partially surround the at least one MEMS device and to form at least one acoustic port that allows sound energy to be received at the at least one MEMS device.

8. The method of claim 7 wherein folding a first portion of the base comprises folding the first portion of the base so as to provide a side wall adjacent to the MEMS device.

9. The method of claim 7 wherein folding a first portion of the base comprises folding the first portion of the base so as to provide a cover for the MEMS device.

10. The method of claim 7 wherein folding a first portion of the base comprises folding the first portion of the base so as to be at least partially under a remaining portion of the base.

11. The method of claim 7 wherein the MEMS device comprises a MEMS die and an electronic device.

12. The method of claim 11 wherein the electronic device comprises an integrated circuit and wherein the MEMS die comprises a microphone.

13. A micro-electromechanical system (MEMS) package comprising:
a first structure;
a second structure disposed on the first structure and forming a first cavity, the second structure having at least one side wall attached to the first structure;
at least one MEMS die disposed in the cavity;
a first acoustic port formed through the sidewall, the first acoustic port providing a passageway to allow sound energy to enter the MEMS package and be received at the at least one MEMS die.

14. The MEMS package of claim 13 further comprising an electronic device disposed in the cavity.

15. The MEMS package of claim 14 wherein the electronic device comprises one of an integrated circuit, a capacitor, a resistor, and an inductor.

16. The MEMS package of claim 13 wherein the MEMS die comprises one of a microphone, a speaker, a receiver, and a conjoined microphone and receiver.

17. The MEMS package of claim 13 wherein the MEMS package is disposed within a cavity of an electronic apparatus, and the electronic apparatus includes a second acoustic port for providing a second passageway to allow sound energy to be received in the second cavity of the electronic apparatus from outside the portable electronic apparatus.

18. The MEMS package of claim 17 wherein the electronic apparatus comprises one of a cellular phone, a laptop, a tablet computer, a personal digital assistant, a camera, a listening device, and a hearing aid.

19. The MEMS package of claim 17 wherein the second cavity includes one of a back volume and a front volume.

20. A micro-electromechanical system (MEMS) package comprising:
a MEMS structure, the MEMS structure including an elongated base;
at least one MEMS device disposed onto the elongated base; and
a first folded portion of the elongated base being configured in folded relation to a remaining portion of the elongated base and at least partially surrounding the at least one
MEMS device, the first folded portion at least partially forming at least one acoustic port to allow sound energy to be received at the MEMS device.

21. The MEMS package of claim 20 wherein the first folded portion provides a side wall for the MEMS package.

22. The MEMS package of claim 20 wherein the first folded portion provides a cover for the MEMS package.

23. The MEMS package of claim 20 wherein the first folded portion is at least partially folded under the remaining portion of the base.
